(19) United States
(12) Patent Application Publication
(10) Pub. No.: US 2025/0038149 A1
(43) Pub. Date: Jan. 30, 2025

(54) SEMICONDUCTOR PACKAGE

(71) Applicant: SAMSUNG ELECTRONICS CO., LTD., SUWON-SI (KR)

(72) Inventors: HYUNGJUN JEON, SUWON-SI (KR); HO-JIN LEE, SUWON-SI (KR)

(21) Appl. No.: 18/428,931

(22) Filed: Jan. 31, 2024

(30) Foreign Application Priority Data
Jul. 27, 2023 (KR) 10-2023-0098180

(51) Int. Cl. H01L 25/065; H01L 23/00; H01L 23/48; H01L 23/498; H01L 25/18

(52) U.S. Cl. CPC H01L 25/0652; H01L 23/481; H01L 23/49838; H01L 24/16; H01L 24/32; H01L 24/73; H01L 25/18; H01L 2224/16145; H01L 2224/16227; H01L 2224/32145; H01L 2224/32225; H01L 2224/73204; H01L 2924/1431; H01L 2924/1436; H01L 2924/1437; H01L 2924/181

(57) ABSTRACT

A semiconductor package includes a first chip and a second chip disposed thereon. The first chip includes a first semiconductor substrate including first and second surfaces, a first circuit layer disposed on the first surface, a first interconnection layer disposed on the first circuit layer, the first interconnection layer including a landing pad, a second interconnection layer disposed on the second surface, and a first penetration via protruding from the second interconnection layer and penetrating the first semiconductor substrate. The second chip includes a second semiconductor substrate including third and fourth surfaces, the fourth surface being closer to the first chip than the third surface, a third interconnection layer disposed on the fourth surface, a second circuit layer disposed between the third interconnection layer and the fourth surface, and a second penetration via penetrating the second semiconductor substrate and connected to the landing pad.

### CROSS-REFERENCE TO RELATED APPLICATIONS

This application claims priority under 35 U.S.C. § 119 to Korean Patent Application No. 10-2023-0098180, filed on Jul. 27, 2023 in the Korean Intellectual Property Office, the disclosure of which is incorporated by reference herein in its entirety.

### TECHNICAL FIELD

Embodiments of the present disclosure relate to a semiconductor package.

### DISCUSSION OF RELATED ART

A semiconductor package is configured to facilitate the use of an integrated circuit chip as a component in an electronic product. Typically, the semiconductor package includes a printed circuit board (PCB) and a semiconductor chip, which is mounted on the PCB and is electrically connected to the PCB using bonding wires or bumps.

### SUMMARY

An embodiment of the inventive concept provides a semiconductor package with improved operation properties.

According to an embodiment of the inventive concept, a semiconductor package includes a first semiconductor chip and a second semiconductor chip disposed on the first semiconductor chip. The first semiconductor chip includes a first semiconductor substrate including a first surface and a second surface facing each other, a first circuit layer disposed on the first surface, a first interconnection layer disposed on the first circuit layer, the first interconnection layer including a landing pad, a second interconnection layer disposed on the second surface, and a first penetration via protruding from the second interconnection layer and penetrating the first semiconductor substrate. The second semiconductor chip includes a second semiconductor substrate including a third surface and a fourth surface facing each other, the fourth surface being closer to the first semiconductor chip than the third surface is to the first semiconductor chip, a third interconnection layer disposed on the fourth surface, a second circuit layer disposed between the third interconnection layer and the fourth surface, and a second penetration via penetrating the second semiconductor substrate and connected to the landing pad.

According to an embodiment of the inventive concept, a semiconductor package includes a first semiconductor chip and a second semiconductor chip disposed on the first semiconductor chip. The first semiconductor chip includes a first semiconductor substrate including a first surface and a second surface facing each other, a first circuit layer disposed on the first surface, a first interconnection layer disposed on the first circuit layer, a second interconnection layer disposed on the second surface, and a first penetration via protruding from the second interconnection layer and penetrating the first semiconductor substrate. The second semiconductor chip includes a second semiconductor substrate including a third surface and a fourth surface, which is closer to the first semiconductor chip than the third surface is to the first semiconductor chip and faces the third surface, a third interconnection layer disposed on the fourth surface, a second circuit layer disposed between the third interconnection layer and the fourth surface, and a second penetration via penetrating the second semiconductor substrate. The first penetration via has a first width in a first direction substantially parallel to a top surface of the first semiconductor substrate and a first height in a second direction substantially perpendicular to the top surface of the first semiconductor substrate. The second penetration via has a second width in the first direction and a second height in the second direction. The second width is larger than the first width, and the second height is larger than the first height. The first penetration via has a shape that is tapered in an opposite manner to the second penetration via.

According to an embodiment of the inventive concept, a semiconductor package includes a package substrate, an interposer substrate disposed on the package substrate, a chip stack and a chip structure, which are spaced apart from each other in a first direction substantially parallel to a top surface of the interposer substrate, and a mold layer covering a side surface of the chip stack, a side surface of the chip structure, and a top surface of the interposer substrate. The chip structure includes a first semiconductor chip, a third semiconductor chip disposed on the first semiconductor chip, and a second semiconductor chip disposed between the first semiconductor chip and the third semiconductor chip. The first semiconductor chip includes a first semiconductor substrate including a first surface and a second surface facing each other, a first circuit layer disposed on the first surface, the first circuit layer including a plurality of fins, an epitaxial pattern, and a landing pad, a first interconnection layer disposed on the first circuit layer, a second interconnection layer disposed on the second surface, and a first penetration via and a second penetration via protruding from the second interconnection layer toward the first surface. The first interconnection layer includes a signal line, and the second interconnection layer includes a power distribution line. An end portion of the first penetration via is placed at a level lower than or about equal to the first surface, and an end portion of the second penetration via is placed at a level higher than the first surface. The second semiconductor chip includes a second semiconductor substrate including a third surface and a fourth surface, which is closer to the first semiconductor chip than the third surface is to the first semiconductor chip and faces the third surface, a third interconnection layer disposed on the fourth surface, a second circuit layer disposed between the third interconnection layer and the fourth surface, and a third penetration via, which penetrates the second semiconductor substrate and is connected to the first interconnection layer.

### BRIEF DESCRIPTION OF THE DRAWINGS

The above and other features of inventive concept will become more apparent by describing in detail embodiments thereof with reference to the accompanying drawings.

FIG. 1 is a cross-sectional view illustrating a semiconductor package according to an embodiment of the inventive concept.

FIG. 2 is an enlarged view of a portion CU of FIG. 1 according to an embodiment of the inventive concept.

FIG. 3 is an enlarged view of the portion CU of FIG. 1 according to an embodiment of the inventive concept.

FIG. 4 is an enlarged view of the portion CU of FIG. 1 according to an embodiment of the inventive concept.

FIG. 5 is an enlarged view of the portion CU of FIG. 1 according to an embodiment of the inventive concept.

FIGS. 6A, 7A, 8A, 9A, 10A, 11A, 12A, 13A, and 14A are diagrams illustrating a method of manufacturing a semiconductor package, according to an embodiment of the inventive concept.

FIGS. 6B, 7B, 8B, 9B, 10B, 11B, 12B, 13B, and 14B are enlarged views illustrating portions ‘aa’, ‘bb’, ‘cc’, ‘dd’, ‘ee’, ‘ff’, ‘gg’, ‘hh’, and ‘ii’ of FIGS. 6A, 7A, 8A, 9A, 10A, 11A, 12A, 13A, and 14A, respectively.

FIGS. 15A, 16A, and 17A are diagrams illustrating a method of manufacturing a semiconductor package, according to an embodiment of the inventive concept.

FIGS. 15B, 16B, and 17B are enlarged views illustrating portions ‘jj’, ‘kk’, and ‘ll’ of FIGS. 15A, 16A, and 17A, respectively.

FIGS. 18A, 19A, and 20A are diagrams illustrating a method of manufacturing a semiconductor package, according to an embodiment of the inventive concept.

FIGS. 18B, 19B, and 20B are enlarged views illustrating portions ‘mm’, ‘nn’, and ‘oo’ of FIGS. 18A, 19A, and 20A, respectively.

### DETAILED DESCRIPTION

Embodiments of the inventive concept will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below.

It will be understood that when a component such as a film, a region, a layer, etc., is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art. It will be further understood that when two components or directions are described as extending substantially parallel or perpendicular to each other, the two components or directions extend exactly parallel or perpendicular to each other, or extend approximately parallel or perpendicular to each other within a measurement error as would be understood by a person having ordinary skill in the art. Other uses of these terms and similar terms to describe the relationships between components should be interpreted in a like fashion.

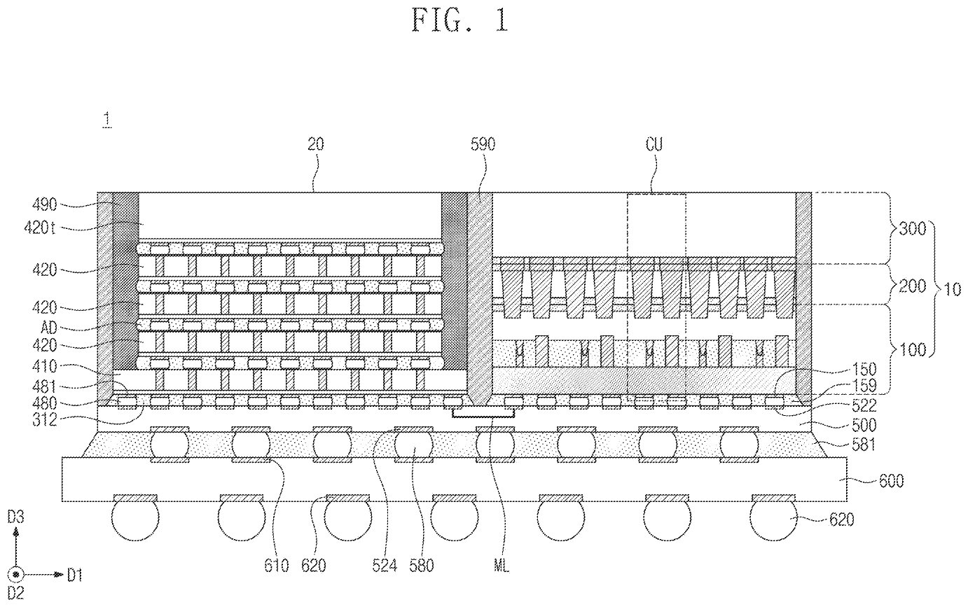

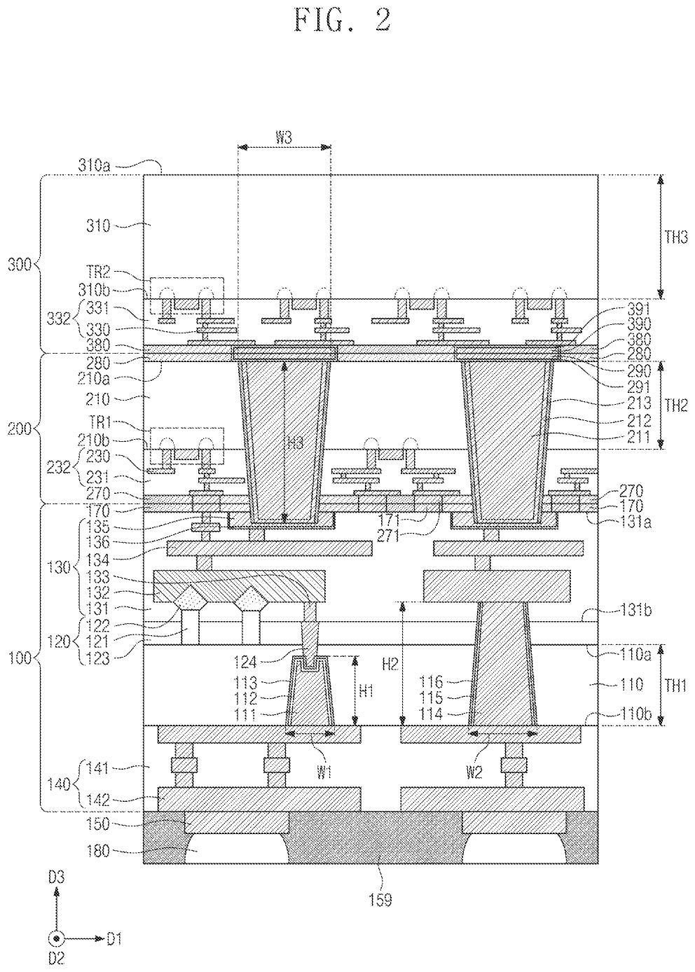

FIG. 1 is a cross-sectional view schematically illustrating a semiconductor package according to an embodiment of the inventive concept. FIG. 2 is an enlarged view of a portion CU of FIG. 1 according to an embodiment of the inventive concept.

Referring to FIGS. 1 and 2, a semiconductor package 1 may include a package substrate 600, an interposer substrate 500, a sub-semiconductor package 20, a chip structure 10, and a first mold layer 590.

In the present specification, a first direction D1 may be defined as a specific direction substantially parallel to a top surface of the package substrate 600. A second direction D2 may be defined as a direction that is substantially parallel to the top surface of the package substrate 600 and is substantially perpendicular to the first direction D1. A third direction D3 may be defined as a direction substantially perpendicular to the top surface of the package substrate 600.

The interposer substrate 500 may be disposed on the package substrate 600. The sub-semiconductor package 20, the chip structure 10, and the first mold layer 590 may be disposed on the interposer substrate 500.

The chip structure 10 may include a first semiconductor chip 100, a second semiconductor chip 200, and a third semiconductor chip 300, which are sequentially stacked. That is, the second semiconductor chip 200 may be disposed between the first semiconductor chip 100 and the third semiconductor chip 300. The first to third semiconductor chips 100, 200, and 300 may form a chiplet structure. In the present specification, the term ‘chiplet’ may mean a structure including a plurality of chips, which are separately configured to realize several functions of an existing chip and are connected to each other through penetration vias.

The first semiconductor chip 100 may include a first semiconductor substrate 110, a first circuit layer 120, a first interconnection layer 130, a first penetration via 111, a second penetration via 114, and a second interconnection layer 140. The first semiconductor chip 100 may be a logic chip.

The first semiconductor substrate 110 may be, for example, a silicon substrate. The first semiconductor substrate 110 may include a first surface 110a and a second surface 110b facing each other. The first surface 110a may be closer to the second semiconductor chip 200 than the second surface 110b is to the second semiconductor chip 200. The first surface 110a may be placed further away from the top surface of the interposer substrate 500 or the top surface of the package substrate 600 than the second surface 110b is to the top surface of the interposer substrate 500 or the top surface of the package substrate 600.

The first circuit layer 120 may be disposed on the first surface 110a of the first semiconductor substrate 110. The first surface 110a may be in contact with a bottom surface of a device isolation layer 123, which will be described below. In the present specification, the first surface 110a may be referred to as a front surface, and the second surface 110b may be referred to as a rear surface. The term “front surface” may mean a surface where the first circuit layer 120 is disposed, while the term “rear surface” may mean a surface where the first circuit layer 120 is not disposed. A thickness TH1 of the first semiconductor substrate 110 in the third direction D3 may range from about 150 nm to about 700 nm.

The first circuit layer 120 may be disposed on the first surface 110a of the first semiconductor substrate 110. In the present specification, the first circuit layer 120 may mean a layer or region, in which an integrated circuit (e.g., a transistor) is provided.

The first circuit layer 120 may include fins 121 and an epitaxial pattern 122. The device isolation layer 123 may fill a space between the fins 121. Each of the fins 121 may vertically protrude in relation to the first surface 110a of the first semiconductor substrate 110 and the device isolation layer 123. The fins 121 may be used as channel structures of fin field-effect transistors (FinFETs), but the inventive concept is not limited to this example. In the following description, the transistor of the first semiconductor chip 100 may be one of, for example, a single or combined FinFET, a nano-wire transistor, a nano-sheet transistor, etc. In an embodiment, the fins 121 may be formed of or include silicon (Si). Each of the epitaxial pattern 122 may be formed of or include at least one of semiconductor materials (e.g., silicon (Si), germanium (Ge), and silicon-germanium (SiGe)). The device isolation layer 123 may include an insulating material. The device isolation layer 123 may be formed of or include an oxide material (e.g., silicon oxide (SiO₂)).

The epitaxial pattern 122, in conjunction with an epitaxial contact 132 described below, may constitute a transistor.

A buried power rail 124 may be provided on the first semiconductor substrate 110. The buried power rail 124 may extend to penetrate the device isolation layer 123 and may be inserted into an upper portion of the first semiconductor substrate 110 near the first surface 110a. In other words, the buried power rail 124 may be a structure that extends toward the second surface 110b. In an embodiment, the buried power rail 124 may include a protruding portion that extends to a level higher than a top surface of the device isolation layer 123. In an embodiment, a top surface of the buried power rail 124 may be placed below a bottom surface of the device isolation layer 123. The buried power rail 124 may be formed of or include at least one of metallic materials (e.g., copper (Cu), cobalt (Co), tungsten (W), and ruthenium (Ru)).

The first interconnection layer 130 may be disposed on the first circuit layer 120. The first interconnection layer 130 may include a first insulating layer 131, and an epitaxial contact 132, a vertical contact 133, first interconnection lines 134, and a landing pad 135, which are provided in the first insulating layer 131.

The first insulating layer 131 may be formed of or include at least one of insulating materials (e.g., silicon oxide (SiO₂)). There may be no observable interface between the first insulating layer 131 and the device isolation layer 123.

The epitaxial contact 132 may be disposed on the epitaxial pattern 122. The epitaxial contact 132 may be a metal layer that extends in the first direction D1 and is in contact with the epitaxial pattern 122.

The vertical contact 133 may be disposed between the epitaxial contact 132 and the buried power rail 124 to connect them to each other. The vertical contact 133 may be a via plug that extends from the epitaxial contact 132 in the second direction D2.

In an embodiment, a plurality of first interconnection lines 134 may be disposed on the epitaxial contact 132. The first interconnection lines 134 may be formed of or include at least one of metallic materials (e.g., copper and aluminum). The first interconnection lines 134 may be configured as signal routing paths. In the present specification, the first interconnection lines 134 may be referred to as signal lines 134.

The landing pad 135 and a first barrier metal 136 may be disposed in an upper portion of the first interconnection layer 130, and here, the first barrier metal 136 may enclose side and bottom surfaces of the landing pad 135. The landing pad 135 may be connected to at least one of the first interconnection lines 134. The landing pad 135 may be formed of or include, for example, copper (Cu) or aluminum (Al). The first barrier metal 136 may be formed of or include at least one of, for example, titanium (Ti), titanium nitride (TiN), or tungsten (W).

A first protection layer 170 may be disposed on the first interconnection layer 130. In other words, the first protection layer 170 may be provided at the topmost level of the first semiconductor chip 100. The first protection layer 170 may be formed of or include at least one of, for example, silicon oxide (SiO₂), silicon nitride (SiN), silicon carbon nitride (SiCN), or silicon oxycarbide (SiCO).

A first bonding pad 171 may be provided in the first protection layer 170. In an embodiment, a plurality of first bonding pads 171 may be arranged in the first direction D1 and/or the second direction D2.

The second interconnection layer 140 may be disposed on the second surface 110b of the first semiconductor substrate 110. The second interconnection layer 140 may include a second insulating layer 141 and second interconnection lines 142 in the second insulating layer 141. The second insulating layer 141 may be formed of or include an insulating material (e.g., silicon oxide). The second interconnection lines 142 may be formed of or include at least one of metallic materials (e.g., copper and aluminum). In the present specification, the second interconnection lines 142 may be referred to as power distribution lines or a power distribution network (PDN).

The first penetration via 111 and the second penetration via 114 may have a structure protruding in relation to the second interconnection layer 140. For example, the first penetration via 111 and the second penetration via 114 may extend from the second surface 110b of the first semiconductor substrate 110 toward the first surface 110a in the third direction D3. An end portion of the first penetration via 111 may be disposed at a level that is lower than or about equal to the first surface 110a. An end portion of the second penetration via 114 may be disposed at a level that is higher than the first surface 110a. The first penetration via 111 and the second penetration via 114 may be spaced apart from each other in the first direction D1.

The first penetration via 111 may serve as a power via. The power via may be configured to deliver electric power, which is supplied from the second interconnection lines 142, to at least one of the first to third semiconductor chips 100, 200, and 300.

The second penetration via 114 may serve as a signal via. The signal via may be used to exchange data signals or control signals between the first to third semiconductor chips 100, 200, and 300.

A second barrier metal 112 may be disposed on side and top surfaces of the first penetration via 111. A first liner 113 may be disposed on side and top surfaces of the second barrier metal 112. The second barrier metal 112 may be interposed between the first penetration via 111 and the first liner 113. The first liner 113 may be interposed between the second barrier metal 112 and the first semiconductor substrate 110.

A lower portion of the buried power rail 124 may penetrate the first semiconductor substrate 110 and be in contact with an upper portion of the first liner 113 and an upper portion of the second barrier metal 112. In other words, the upper portion of the first liner 113 may be in contact with a portion of a side surface of the buried power rail 124, and the upper portion of the second barrier metal 112 may enclose a bottom surface of the buried power rail 124 and a portion of the side surface of the buried power rail 124.

The first penetration via 111 may have a first width W1 (also referred to as a first diameter) in the first direction D1. The first penetration via 111 may have a first height H1 in the third direction D3. The first width W1 may range from about 10 nm to about 100 nm. The first height H1 may be less than or about equal to three times the first width W1.

The second barrier metal 112 may be formed of or include at least one of, for example, titanium (Ti), titanium nitride (TiN), or tungsten (W). The first liner 113 may be formed of or include at least one of, for example, silicon oxide (SiO₂), silicon nitride (SiN), silicon carbon nitride (SiCN), or silicon oxycarbide (SiCO). The second barrier metal 112 and the first liner 113 may prevent a metallic material, which is contained in the first penetration via 111, from being diffused into the first semiconductor substrate 110.

A third barrier metal 115 may be disposed on side and top surfaces of the second penetration via 114. A second liner 116 may be disposed on a side surface of the third barrier metal 115. The third barrier metal 115 may be interposed between the second penetration via 114 and the second liner 116.

The third barrier metal 115 disposed on the second penetration via 114 may be in contact with at least one of the first interconnection lines 134. For example, the second penetration via 114 may extend into the first interconnection layer 130 and may be electrically connected to a gate electrode in the first circuit layer 120 through at least one of the first interconnection lines 134.

The second penetration via 114 may have a second width W2 in the first direction D1. The second penetration via 114 may have a second height H2 in the third direction D3. The second width W2 may range from about 100 nm to about 999 nm. The second height H2 may be larger than the first height H1.

The third barrier metal 115 may be formed of or include at least one of, for example, titanium (Ti), titanium nitride (TiN), or tungsten (W). The second liner 116 may be formed of or include at least one of, for example, silicon oxide (SiO₂), silicon nitride (SiN), silicon carbon nitride (SiCN), or silicon oxycarbide (SiCO).

Chip pads 150 may be disposed on the second interconnection layer 140. The chip pads 150 may be formed of or include at least one of, for example, aluminum or copper. First connection terminals 180 may be disposed on the chip pads 150, respectively. The first connection terminal 180 may include, for example, a solder ball, a solder bump, or a solder pillar.

A first under-fill pattern 159 may cover a side surface of the first connection terminal 180. The first under-fill pattern 159 may be formed of or include an insulating material (e.g., an epoxy resin).

The second semiconductor chip 200 may include a second semiconductor substrate 210, a third penetration via 211, a third interconnection layer 232, first transistors TR1, a second protection layer 270, and a third protection layer 280. In an embodiment, the second semiconductor chip 200 may be a memory chip (e.g., SRAM or DRAM chip) or may be a logic chip including a logic circuit. Elements constituting the second semiconductor chip 200 may be variously changed depending on the structure and design of the second semiconductor chip 200 and are not limited to the elements described above.

The second semiconductor substrate 210 may be, for example, a silicon substrate. The second semiconductor substrate 210 may include a third surface 210a and a fourth surface 210b facing each other. The fourth surface 210b may be closer to the first semiconductor chip 100 than the third surface 210a is to the first semiconductor chip 100. A circuit layer including the first transistors TR1 may be disposed on the fourth surface 210b. The second semiconductor substrate 210 may have a thickness TH2 that is less than or equal to about 50 μm.

The third interconnection layer 232 may be disposed below the fourth surface 210b of the second semiconductor substrate 210. The third interconnection layer 232 may include a third insulating layer 231 and third interconnection lines 230, which are provided in the third insulating layer 231. Some of the third interconnection lines 230 may be connected to the first transistors TR1 and a second bonding pad 271. The third insulating layer 231 may be formed of or include at least one of insulating materials (e.g., silicon oxide (SiO₂)). The third interconnection lines 230 may be formed of or include at least one of metallic materials (e.g., copper and aluminum).

The first transistors TR1 may be disposed on the third interconnection lines 230. For example, a circuit layer including the first transistors TR1 may be disposed between the third interconnection layer 232 and the fourth surface 210b. Each of the first transistors TR1 may include source, drain, and gate electrodes. If the second semiconductor chip 200 is a logic chip, the first transistors TR1 may be configured to execute data processing operations (e.g., a logical operation and an operation of processing control signals) of the logic chip. If the second semiconductor chip 200 is a memory chip, the first transistors TR1 may be configured to execute operations of storing or accessing data in or to the memory chip. That is, the first transistors TR1 may be modified or combined in various manners depending on the type of the second semiconductor chip 200, and may be configured to achieve other various functions of the semiconductor chip that are not described herein.

The second protection layer 270 may be disposed below the third interconnection layer 232. The second protection layer 270 may be formed of or include at least one of, for example, silicon oxide (SiO₂), silicon nitride (SiN), silicon carbon nitride (SiCN), or silicon oxycarbide (SiCO).

The first and second semiconductor chips 100 and 200 may be bonded to each other to form a hybrid bonding structure between the first protection layer 170 and the second protection layer 270 and may be in contact with each other. In the present specification, the hybrid bonding structure may mean a bonding structure which is formed by two materials, which are of the same kind and are fused at an interface therebetween.

The second bonding pad 271 may be disposed on the first bonding pad 171. A bottom surface of the second bonding pad 271 may be exposed from the second protection layer 270. The second bonding pad 271 may be in contact with the first bonding pad 171. In an embodiment, a plurality of second bonding pads 271 may be arranged in the first direction D1 and/or the second direction D2.

The third protection layer 280 may be disposed on the third surface 210a of the second semiconductor substrate 210. The third protection layer 280 may be formed of or include at least one of, for example, silicon oxide (SiO₂), silicon nitride (SiN), silicon carbon nitride (SiCN), or silicon oxycarbide (SiCO).

A first connection pad 290 may be disposed on the third penetration via 211. A top surface of the first connection pad 290 may be exposed from the third protection layer 280. A fourth barrier metal 291 may cover bottom and side surfaces of the first connection pad 290. The fourth barrier metal 291 may be formed of or include at least one of, for example, titanium (Ti), titanium nitride (TiN), or tungsten (W).

The third penetration via 211 may penetrate the second semiconductor substrate 210, the third insulating layer 231, the first protection layer 170, the second protection layer 270, and an upper portion of the landing pad 135. The first and second semiconductor chips 100 and 200 may be connected to each other through the third penetration via 211. In an embodiment, a plurality of third penetration vias 211 may be spaced apart from each other in the first direction D1 and/or the second direction D2.

The third penetration via 211 may have a shape which is tapered in an opposite manner to those of the first and second penetration vias 111 and 114.

The third penetration via 211 may have a third width W3 in the first direction D1. The third penetration via 211 may have a third height H3 in the third direction D3. The third width W3 may be larger than the first width W1 and the second width W2. The third width W3 may be less than or equal to about 100 μm. The third height H3 may be larger than the first height H1 and the second height H2. The third height H3 may be less than or equal to about 20 times the third width W3.

A fifth barrier metal 212 may be disposed on side and bottom surfaces of the third penetration via 211. A third liner 213 may be disposed on a side surface of the fifth barrier metal 212. The fifth barrier metal 212 may be interposed between the third penetration via 211 and the third liner 213.

The fifth barrier metal 212 may be formed of or include at least one of, for example, titanium (Ti), titanium nitride (TiN), or tungsten (W). The third liner 213 may be formed of or include at least one of, for example, silicon oxide (SiO₂), silicon nitride (SiN), silicon carbon nitride (SiCN), or silicon oxycarbide (SiCO).

The third semiconductor chip 300 may include a third semiconductor substrate 310, a fourth interconnection layer 332, second transistors TR2, and a fourth protection layer 380. As an example, the third semiconductor chip 300 may be a memory chip (e.g., an S-RAM or DRAM chip) or a logic chip including a logic circuit. Elements constituting the third semiconductor chip 300 may be variously changed depending on the structure and design of the third semiconductor chip 300 and are not limited to the elements described above.

The third semiconductor substrate 310 may be, for example, a silicon substrate. The third semiconductor substrate 310 may include a fifth surface 310a and a sixth surface 310b facing each other. The sixth surface 310b may be closer to the second semiconductor chip 200 than the fifth surface 310a is to the second semiconductor chip 200. A circuit layer including the second transistors TR2 may be disposed on the sixth surface 310b. The third semiconductor substrate 310 may have a thickness TH3 ranging from about 100 μm to about 1 mm.

The fourth interconnection layer 332 may be disposed below the sixth surface 310b of the third semiconductor substrate 310. The fourth interconnection layer 332 may include a fourth insulating layer 331 and fourth interconnection lines 330, which are provided in the fourth insulating layer 331. At least one of the fourth interconnection lines 330 may be connected to the second transistors TR2 and a second connection pad 390. The fourth insulating layer 331 may be formed of or include at least one of insulating materials (e.g., silicon oxide (SiO₂)). The fourth interconnection lines 330 may be formed of or include at least one of metallic materials (e.g., copper and aluminum).

The second transistors TR2 may be disposed on the fourth interconnection lines 330. For example, a circuit layer including the second transistors TR2 may be disposed between the fourth interconnection layer 332 and the sixth surface 310b. The second transistors TR2 may include source, drain, and gate electrodes. If the third semiconductor chip 300 is a logic chip, the second transistors TR2 may be configured to execute data processing operations (e.g., a logical operation and an operation of processing control signals) of the logic chip. If the third semiconductor chip 300 is a memory chip, the second transistors TR2 may be configured to execute operations of storing or accessing data in or to the memory chip. That is, the second transistors TR2 may be modified or combined in various manners depending on the type of the third semiconductor chip 300, and may be configured to achieve other various functions of the semiconductor chip that are not described herein.

The fourth protection layer 380 may be disposed below the fourth interconnection layer 332. The fourth protection layer 380 may be formed of or include at least one of, for example, silicon oxide (SiO₂), silicon nitride (SiN), silicon carbon nitride (SiCN), or silicon oxycarbide (SiCO).

The second and third semiconductor chips 200 and 300 may be bonded to each other to form a hybrid bonding structure between the third and fourth protection layers 280 and 380 and may be in contact with each other.

The second connection pad 390 may be disposed on the first connection pad 290. A bottom surface of the second connection pad 390 may be exposed from the fourth protection layer 380. The bottom surface of the second connection pad 390 may be in contact with a top surface of the first connection pad 290. A fifth barrier metal 391 may cover top and side surfaces of the second connection pad 390. The fifth barrier metal 391 may be formed of or include at least one of, for example, titanium (Ti), titanium nitride (TiN), or tungsten (W).

The sub-semiconductor package 20 may be spaced apart from the chip structure 10 in the first direction D1 and/or the second direction D2. In the present specification, the sub-semiconductor package 20 may be referred to as a chip stack 20 or a high bandwidth memory (HBM) 20. The sub-semiconductor package 20 may include a fourth semiconductor chip 410 and fifth semiconductor chips 420 and 420t and a second mold layer 490, which are disposed on the fourth semiconductor chip 410. In the present specification, the fourth semiconductor chip 410 may be referred to as a base chip 410, and the fifth semiconductor chips 420 and 420t may be referred to as memory chips 420 and 420t.

The base chip 410 may be a logic chip. In an embodiment, the base chip 410 may be a memory controller.

The memory chips 420 and 420t may be stacked on the base chip 410 in the third direction D3. The memory chips 420 and 420t may be semiconductor chips that include the same circuit and are of the same type. The memory chips 420 and 420t may be, for example, D-RAM chips or NAND FLASH memory chips.

All of the base chip 410 and the memory chips 420 and 420t may include a circuit layer. The base chip 410 and memory chips 420 may include penetration vias. In embodiments, the topmost memory chip 420t, which is the uppermost one of the memory chips 420 and 420t, does not include the penetration vias therein. However, in an embodiment, the topmost memory chip 420t may be configured to include the penetration vias, unlike the illustrated structure. The penetration vias of the base chip 410 and the penetration vias of the memory chip 420 adjacent thereto may be connected to each other through micro-bumps. The penetration vias disposed between the memory chips 420, which are adjacent to each other, may be connected to each other through micro-bumps.

Adhesive layers AD may be interposed between the base chip 410 and the memory chip 420, which are adjacent to each other, and between the memory chips 420, which are adjacent to each other. In an embodiment, the adhesive layers AD may be a non-conductive film (NCF) containing polymer.

The second mold layer 490 may cover a top surface of the base chip 410, side surfaces of the memory chips 420 and 420t, and side surfaces of the adhesive layers AD. A top surface of the topmost memory chip 420t may be exposed from the second mold layer 490. The second mold layer 490 may include an insulating material (e.g., an epoxy molding compound (EMC)).

Second connection terminals 480 may be disposed below the base chip 410. For example, the second connection terminals 480 may be respectively disposed on chip stack pads 481, which are provided below the base chip 410. The second connection terminal 480 may include, for example, a solder ball, a solder bump, or a solder pillar. A second under-fill pattern 312 may cover a side surface of the second connection terminal 480. The second under-fill pattern 312 may include an insulating material (e.g., an epoxy resin).

The package substrate 600 may be, for example, a printed circuit board (PCB). The package substrate 600 may include upper pads 610 and lower pads 620, which are respectively provided on top and bottom surfaces thereof or in upper or lower portions thereof. An outer connection terminal 680 may be provided on each of the lower pads 620 and may be connected to an external board (e.g., a motherboard). The outer connection terminal 680 may be formed of or include at least one of conductive materials (e.g., solder materials).

The interposer substrate 500 may be, for example, a silicon interposer substrate. The interposer substrate 500 may include a lower interposer pad 524 disposed on a bottom surface thereof, an upper interposer pad 522 disposed on a top surface thereof, and a metal line ML. The chip structure 10 and the sub-semiconductor package 20 may be electrically connected to the package substrate 600 through the interposer substrate 500.

Third connection terminals 580 may be disposed between the interposer substrate 500 and the package substrate 600. The third connection terminal 580 may be formed of or include at least one of conductive materials (e.g., solder materials). A third under-fill pattern 581 may be disposed on the package substrate 600 to cover a side surface of each of the third connection terminals 580. The third under-fill pattern 581 may include an insulating material (e.g., an epoxy resin).

The first mold layer 590 may be disposed on the interposer substrate 500. The first mold layer 590 may cover a top surface of the interposer substrate 500, a side surface of the sub-semiconductor package 20, and a side surface of the chip structure 10. The first mold layer 590 may be formed of or include an insulating material (e.g., an epoxy molding compound (EMC)).

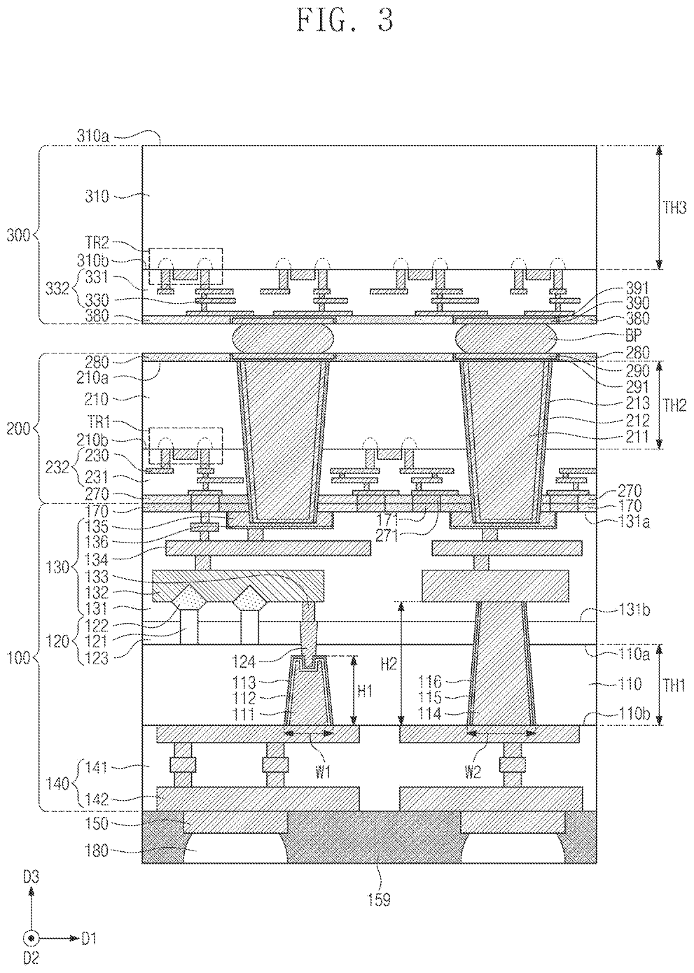

FIG. 3 is an enlarged view of the portion CU of FIG. 1 according to an embodiment of the inventive concept. An element previously described with reference to FIGS. 1 and 2 may be identified by the same reference number without repeating an overlapping description thereof.

Referring to FIG. 3, a connection bump BP may be disposed between the second semiconductor chip 200 and the third semiconductor chip 300. For example, the connection bump BP may be interposed between a top surface of the first connection pad 290 and a bottom surface of the second connection pad 390. The connection bump BP may be in contact with the top surface of the first connection pad 290 and the bottom surface of the second connection pad 390. In an embodiment, a plurality of connection bumps BP may be arranged in the first direction D1 and/or the second direction D2. The connection bump BP may be formed of or include at least one of, for example, tin, bismuth, lead, silver, or alloys.

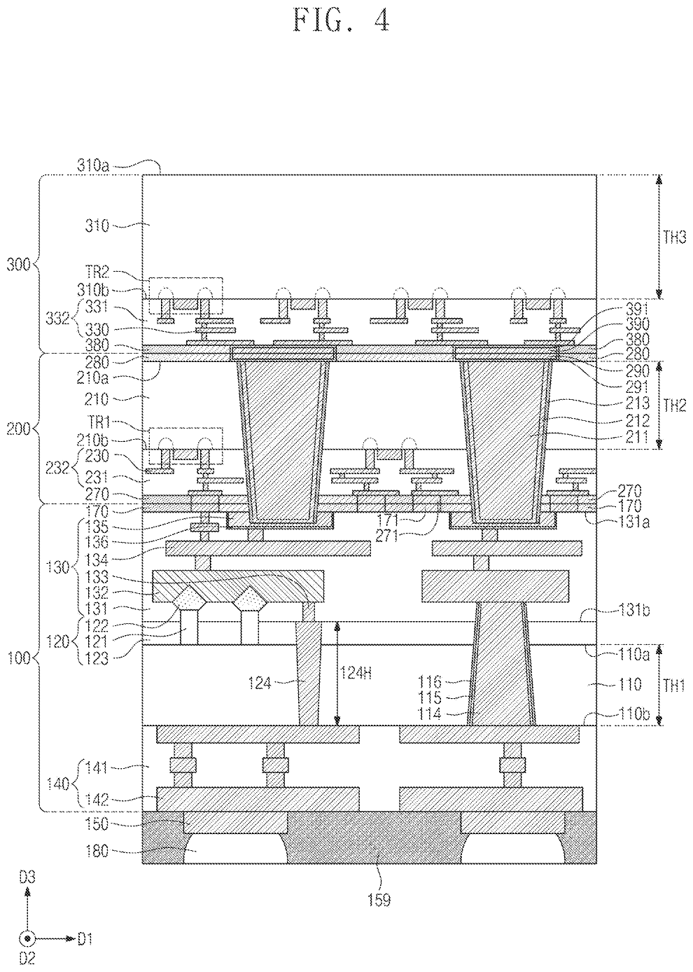

FIG. 4 is an enlarged view of the portion CU of FIG. 1 according to an embodiment of the inventive concept. An element previously described with reference to FIGS. 1 and 2 may be identified by the same reference number without repeating an overlapping description thereof.

Referring to FIG. 4, in an embodiment, the first semiconductor chip 100 does not include the first penetration via 111. The buried power rail 124, which penetrates the device isolation layer 123 and the first semiconductor substrate 110 and is connected to the second interconnection lines 142 of the second interconnection layer 140, may be provided in place of the first penetration via 111. That is, the buried power rail 124 may be disposed between the vertical contact 133 and the second interconnection lines 142. A height 124H of the buried power rail 124 may be substantially equal to a sum of the thickness TH1 of the first semiconductor substrate 110 and the thickness of the device isolation layer 123.

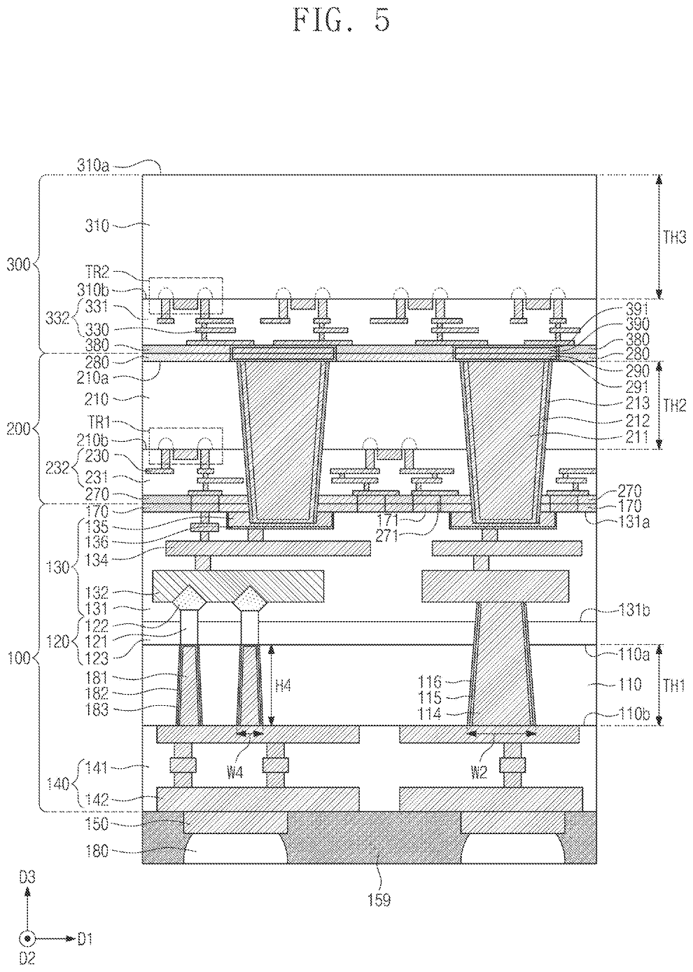

FIG. 5 is an enlarged view illustrating a portion (e.g., CU of FIG. 1) of a semiconductor package according to an embodiment of the inventive concept. An element previously described with reference to FIGS. 1 and 2 may be identified by the same reference number without repeating an overlapping description thereof.

Referring to FIG. 5, in an embodiment, the first semiconductor chip 100 does not include the first penetration via 111 and the buried power rail 124. A fourth penetration via 181, which protrudes from the second interconnection layer 140, may be provided in place of the first penetration via 111 and the buried power rail 124. For example, the fourth penetration via 181 may extend from the second surface 110b of the first semiconductor substrate 110 toward the first surface 110a in the third direction D3. In an embodiment, a plurality of fourth penetration vias 181 may be spaced apart from each other in the first direction D1 and/or the second direction D2.

A sixth barrier metal 182 may be disposed on side and top surfaces of the fourth penetration via 181. A fourth liner 183 may be disposed on a side surface of the sixth barrier metal 182. The sixth barrier metal 182 may be interposed between the fourth penetration via 181 and the fourth liner 183. The fourth liner 183 may be interposed between the sixth barrier metal 182 and the first semiconductor substrate 110.

The sixth barrier metal 182 disposed on the fourth penetration via 181 may be in contact with a bottom surface of the fin 121. The fourth penetration via 181 may be disposed between the fins 121 and the second interconnection lines 142, in the first semiconductor substrate 110. That is, the fourth penetration via 181 may penetrate the first semiconductor substrate 110 and may be connected to the fins 121, and the first semiconductor chip 100 may be used to deliver an electric power, which is supplied from the second interconnection lines 142 through the fourth penetration via 181, to the fins 121.

The fourth penetration via 181 may have a fourth width W4 in the first direction D1. The fourth width W4 may be smaller than the second width W2 of the second penetration via 114. A length of the fourth width W4 may be less than or equal to about 50 nm. The fourth penetration via 181 may have a fourth height H4 in the third direction D3. The fourth height H4 may be less than or equal to about three times the fourth width W4. The fourth height H4 may be substantially equal to the thickness TH1 of the first semiconductor substrate 110.

The sixth barrier metal 182 may be formed of or include at least one of, for example, titanium (Ti), titanium nitride (TiN), or tungsten (W). The fourth liner 183 may be formed of or include at least one of, for example, silicon oxide (SiO₂), silicon nitride (SiN), silicon carbon nitride (SiCN), or silicon oxycarbide (SiCO).

Referring to a semiconductor package according to a comparative example, a bulk silicon substrate may be placed on the first semiconductor chip 100. In this case, the presence of the bulk silicon substrate may lead to an increase in the thickness of the semiconductor package.

By contrast, referring to the semiconductor package 1 according to an embodiment of the inventive concept, the third semiconductor chip 300 may be mounted on the first semiconductor chip 100, and the second semiconductor chip 200 may be disposed between the first semiconductor chip 100 and the third semiconductor chip 300. The first semiconductor chip 100 may be a logic chip. Each of the second and third semiconductor chips 200 and 300 may be a logic chip or a memory chip. The first and second semiconductor chips 100 and 200 may be connected to each other through the third penetration via 211. In this case, since various semiconductor chips, which are configured to execute various functions of the logic or memory chip, are placed on the first semiconductor chip 100, the operation efficiency of the semiconductor package 1 may be improved compared to the conventional structure with the bulk silicon substrate.

In addition, since the signal lines 134 and the power distribution lines 142 are disposed on and below the first semiconductor chip 100, a total thickness of the semiconductor package 1 may be reduced.

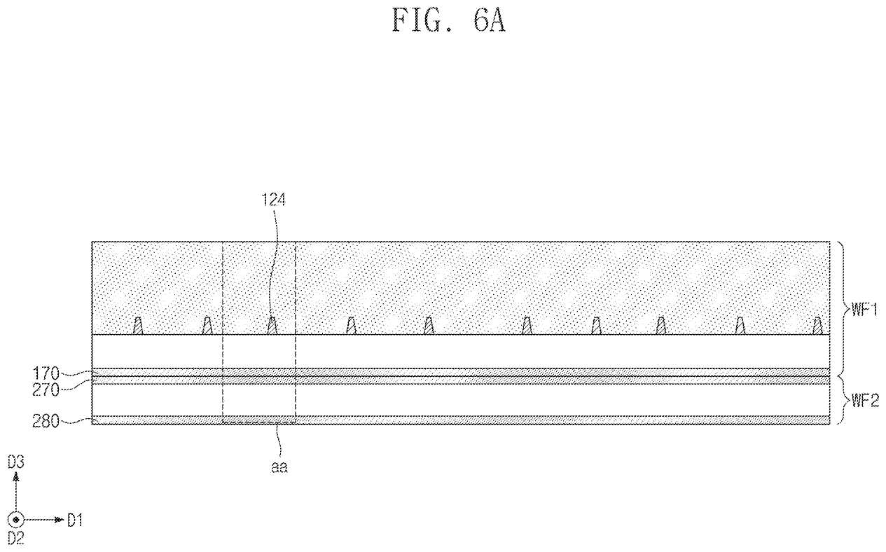

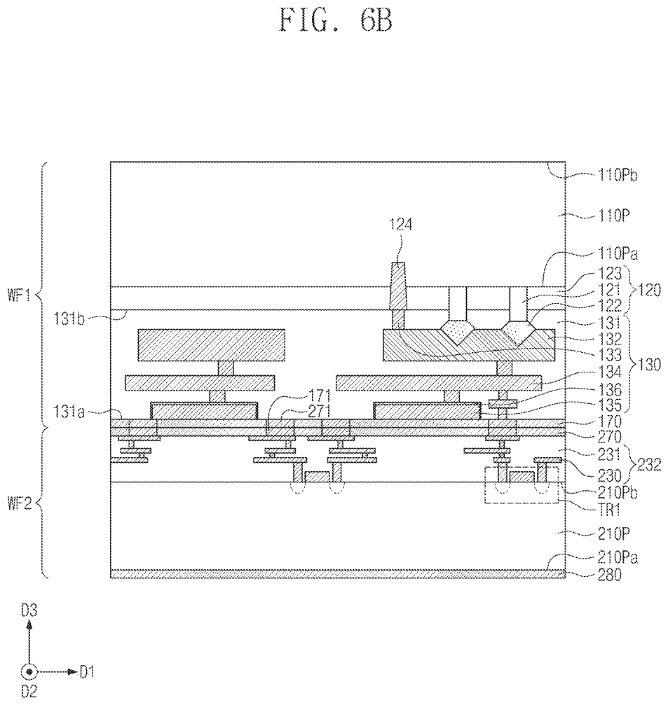

FIGS. 6A, 7A, 8A, 9A, 10A, 11A, 12A, 13A, and 14A are diagrams illustrating a method of manufacturing a semiconductor package, according to an embodiment of the inventive concept.

FIGS. 6B, 7B, 8B, 9B, 10B, 11B, 12B, 13B, and 14B are enlarged views illustrating portions ‘aa’, ‘bb’, ‘cc’, ‘dd’, ‘ee’, ‘ff’, ‘gg’, ‘hh’, and ‘ii’ of FIGS. 6A, 7A, 8A, 9A, 10A, 11A, 12A, 13A, and 14A, respectively.

Referring to FIGS. 6A and 6B, a first wafer WF1 and a second wafer WF2 may be provided. The first wafer WF1 may include a first preliminary semiconductor substrate 110P, the first circuit layer 120, the first interconnection layer 130, and the first protection layer 170.

The first preliminary semiconductor substrate 110P may include a seventh surface 110Pa and an eighth surface 110Pb facing each other. The seventh surface 110Pa may be closer to the second wafer WF2 than the eighth surface 110Pb is to the second wafer WF2.

For example, the fins 121 may be formed by patterning a surface of the first preliminary semiconductor substrate 110P. Each of the fins 121 may be used as a current channel of a transistor. Although each of the fins 121 is illustrated to have the fin structure of the FinFET, the fins 121 may be fin structures (e.g., nano-wires or nano-sheets) for the nano-wire transistor or the nano-sheet transistor or combinations thereof. In an embodiment, a space between the fins 121 may be filled with the device isolation layer 123, which is formed of silicon oxide (SiO₂). The buried power rail 124 may penetrate the device isolation layer 123 and a portion of the first preliminary semiconductor substrate 110P.

Epitaxial patterns 122 may be formed on the fins 121. In an embodiment, the epitaxial patterns 122 may be used as active regions (e.g., source/drain regions) of a transistor and may be formed of, for example, silicon (Si). The vertical contact 133 and the epitaxial contact 132 may be formed simultaneously or sequentially. Next, the first interconnection layer 130 may be formed on the epitaxial contact 132. Thereafter, the first protection layer 170 may be formed on the first interconnection layer 130.

The second wafer WF2 may include a second preliminary semiconductor substrate 210P, the third interconnection layer 232, the second protection layer 270, and the third protection layer 280. The second preliminary semiconductor substrate 210P may include a ninth surface 210Pa and a tenth surface 210Pb facing each other. The tenth surface 210Pb may be closer to the first wafer WF1 than the ninth surface 210Pa is to the first wafer WF1. Thereafter, a wafer-to-wafer bonding process may be performed. For example, the second wafer WF2 may be placed on and in contact with the first wafer WF1. The second wafer WF2 may be directly bonded to the first wafer WF1 through a direct bonding method, without using any adhesive layer. During the bonding process, the first and second wafers WF1 and WF2 may be exposed to a thermally hot environment.

For example, the first protection layer 170 and the second protection layer 270 may be bonded to each other to form a hybrid bonding structure. In addition, a metal-to-metal hybrid bonding process may be performed using the surface activation, at an interface between the first and second bonding pads 171 and 271, which are included in the first and second protection layers 170 and 270.

The first and second wafers WF1 and WF2 may be bonded to each other by bonding the first and second protection layers 170 and 270 to each other and bonding the first and second bonding pads 171 and 271, which are provided in the first and second protection layers 170 and 270, to each other.

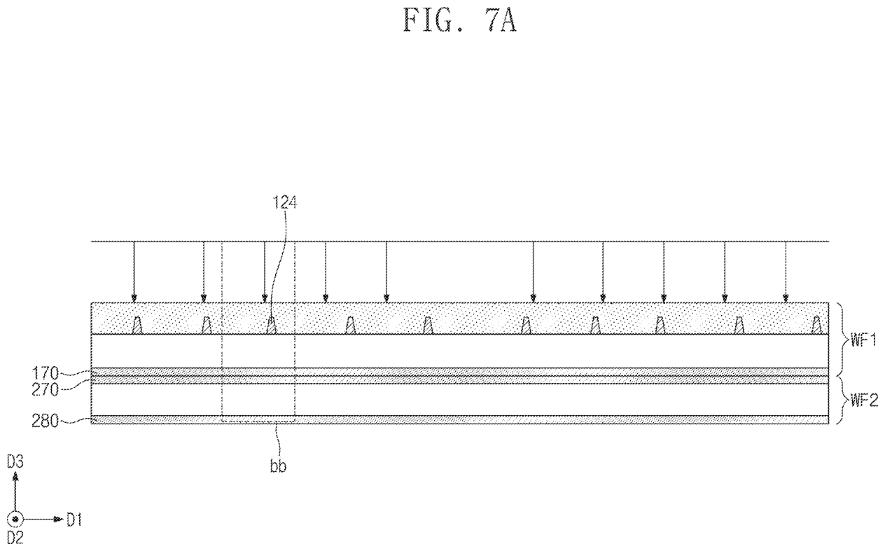

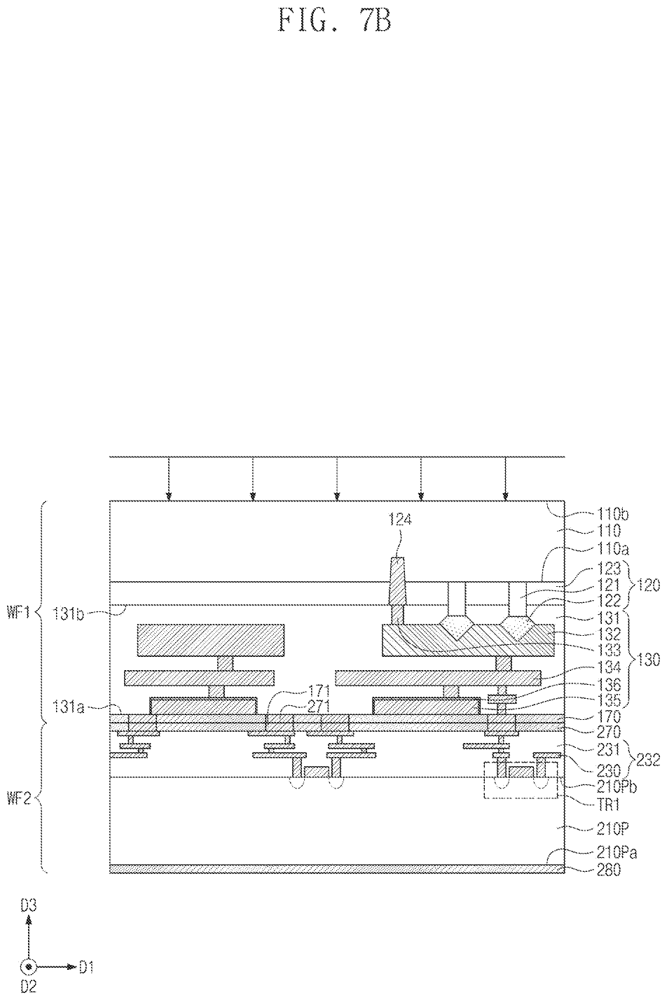

Referring to FIGS. 7A and 7B, a portion of the first preliminary semiconductor substrate 110P may be removed by performing, for example, a chemical-mechanical polishing (CMP) process, a dry etching process, or a grinding process on the eighth surface 110Pb of the first preliminary semiconductor substrate 110P. A thickness of the first preliminary semiconductor substrate 110P in the third direction D3 may be reduced by the etching process. The first semiconductor substrate 110 may be formed as a result of reducing the thickness of the first preliminary semiconductor substrate 110P.

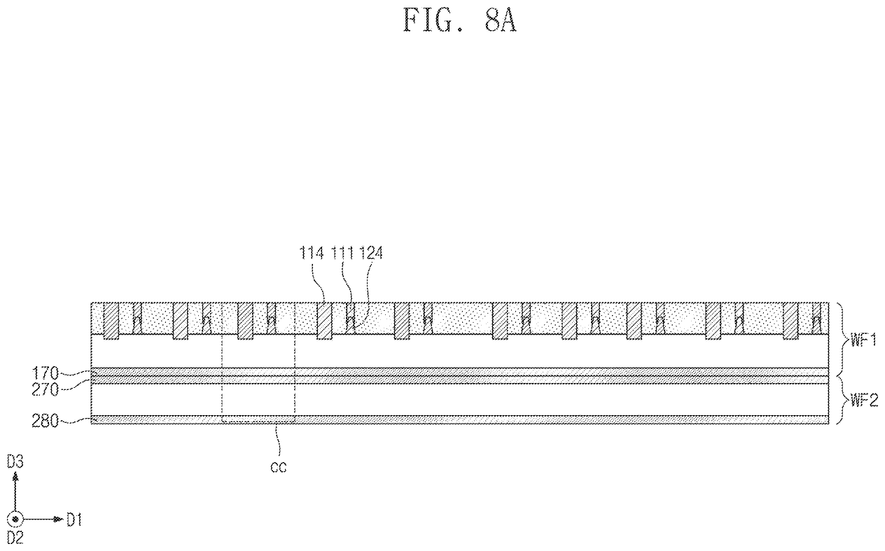

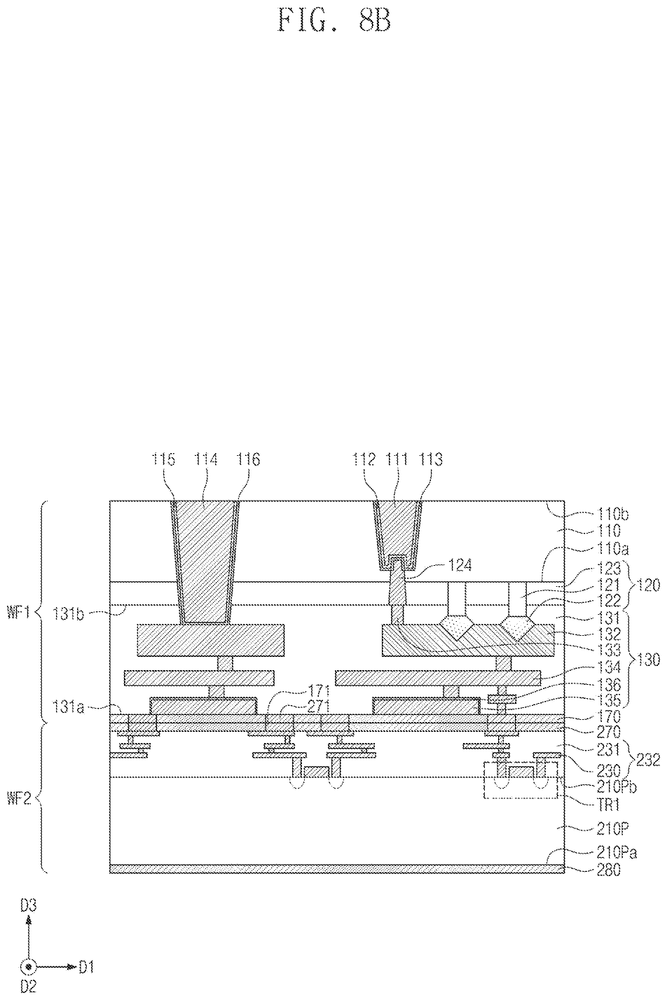

Referring to FIGS. 8A and 8B, the first penetration via 111 and the second penetration via 114 may be formed. The formation of the first penetration via 111 may include performing an etching process on the second surface 110b of the first semiconductor substrate 110 to form a via hole exposing an upper portion of the buried power rail 124, forming the first liner 113 on side and bottom surfaces of the via hole and the upper portion of the buried power rail 124, forming the second barrier metal 112 on the first liner 113, and filling the via hole, which is covered with the first liner 113 and the second barrier metal 112, with a metallic material.

The formation of the second penetration via 114 may include performing an etching process on the first semiconductor substrate 110 and the device isolation layer 123 to form a via hole exposing the first interconnection line 134, forming the second liner 116 on a side surface of the via hole, forming the third barrier metal 115 on the second liner 116 and a bottom surface of the via hole, and filling the via hole, which is covered with the second liner 116 and the third barrier metal 115, with a metallic material.

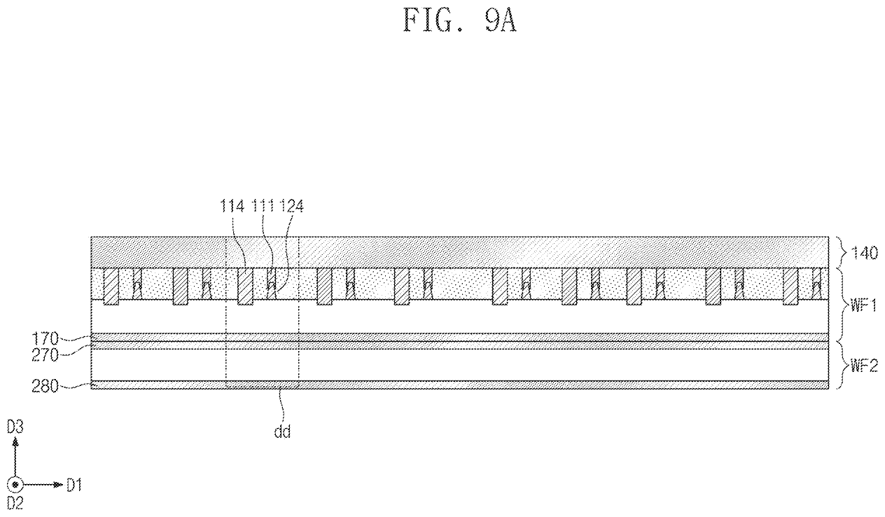

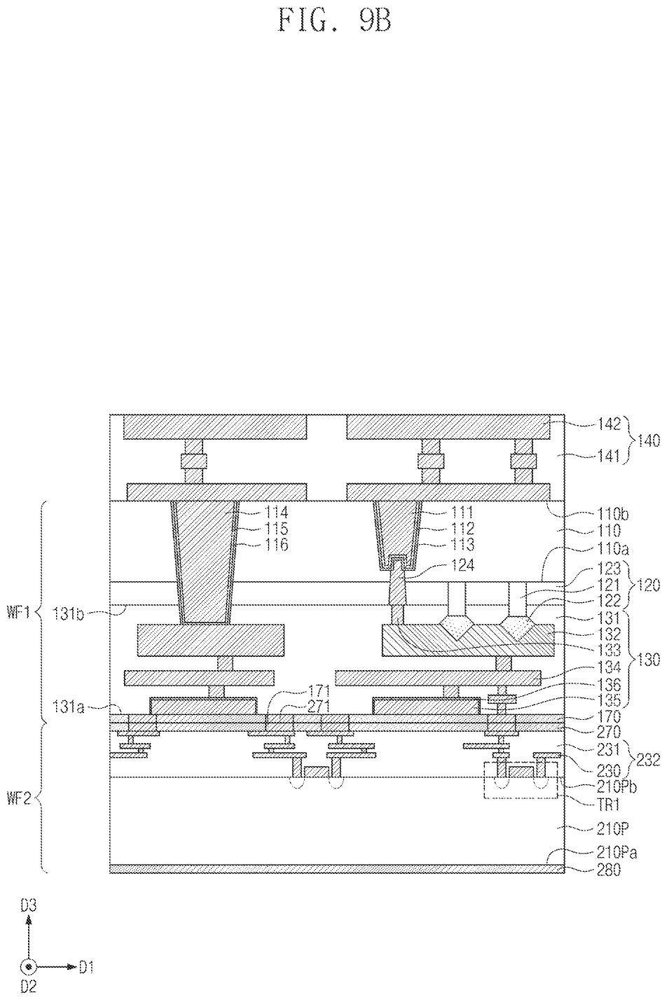

Referring to FIGS. 9A and 9B, the second interconnection layer 140 may be formed on the second surface 110b of the first semiconductor substrate 110. The second interconnection layer 140 may be connected to the first penetration via 111 and the second penetration via 114.

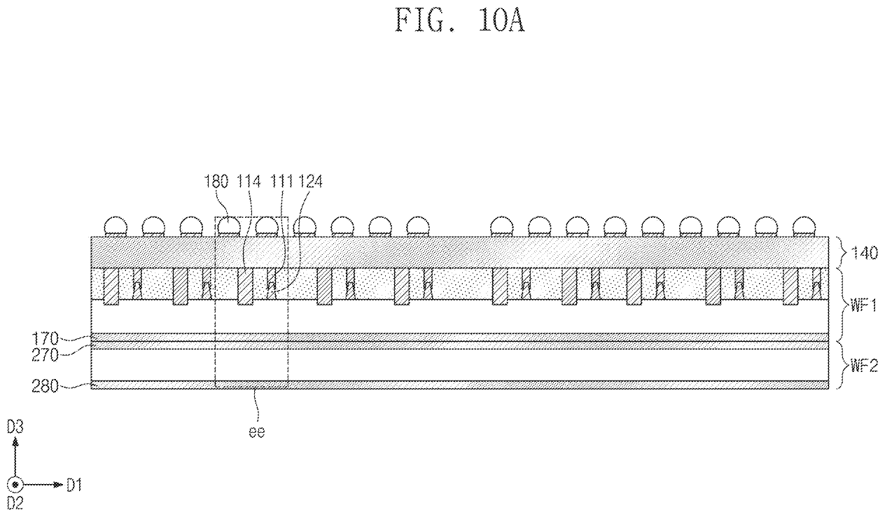

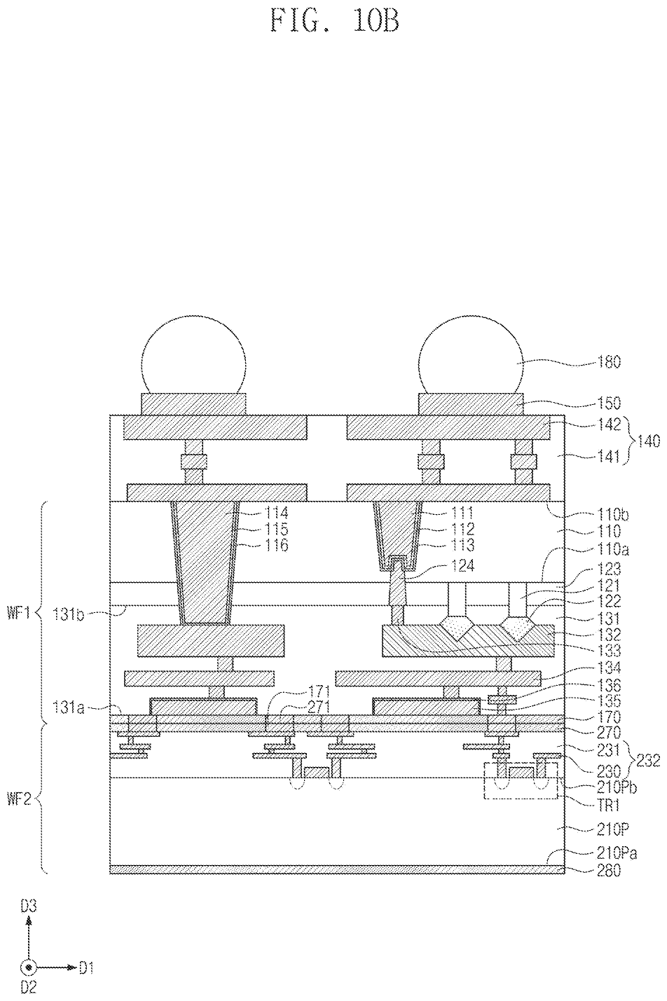

Referring to FIGS. 10A and 10B, the chip pads 150 may be formed on the second interconnection layer 140. Next, the first connection terminals 180 may be provided on and attached to the chip pads 150, respectively.

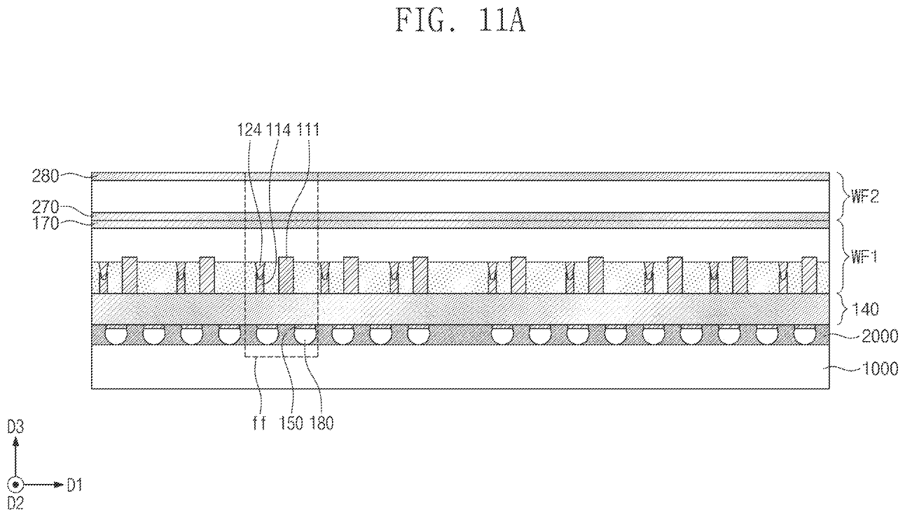

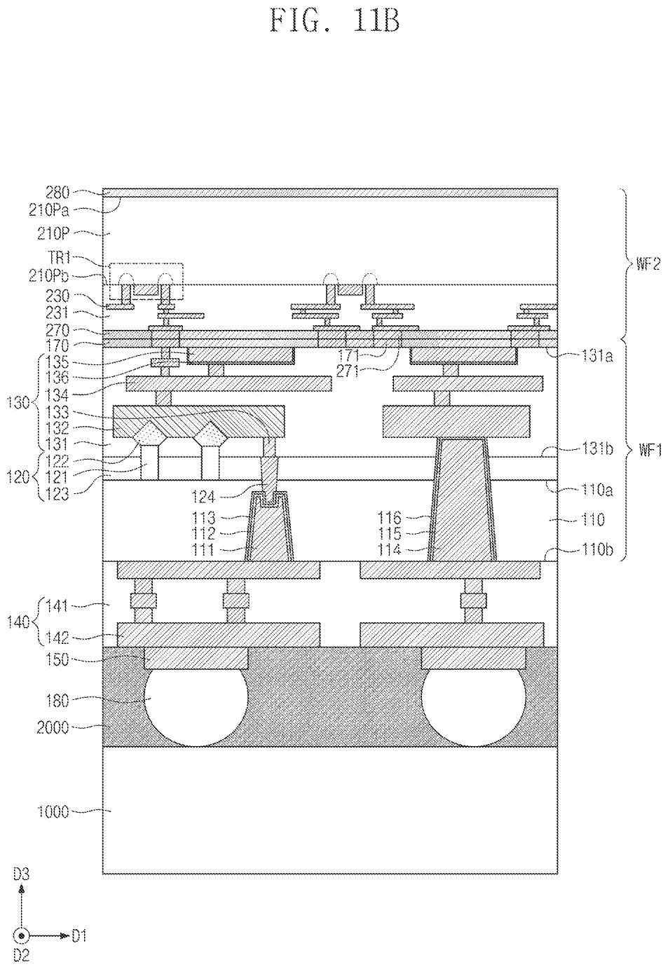

Referring to FIGS. 11A and 11B, the first wafer WF1, the second wafer WF2, and the second interconnection layer 140 may be inverted. Next, a carrier substrate 1000 and a release layer 2000, which is attached to the carrier substrate 1000, may be prepared. Thereafter, the release layer 2000 may be attached to a bottom surface of the second interconnection layer 140 to enclose the chip pads 150 and the first connection terminals 180.

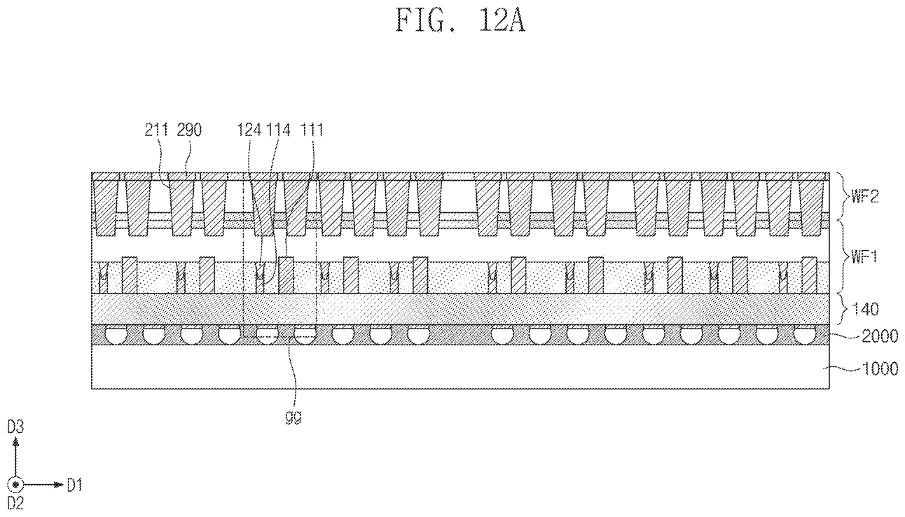

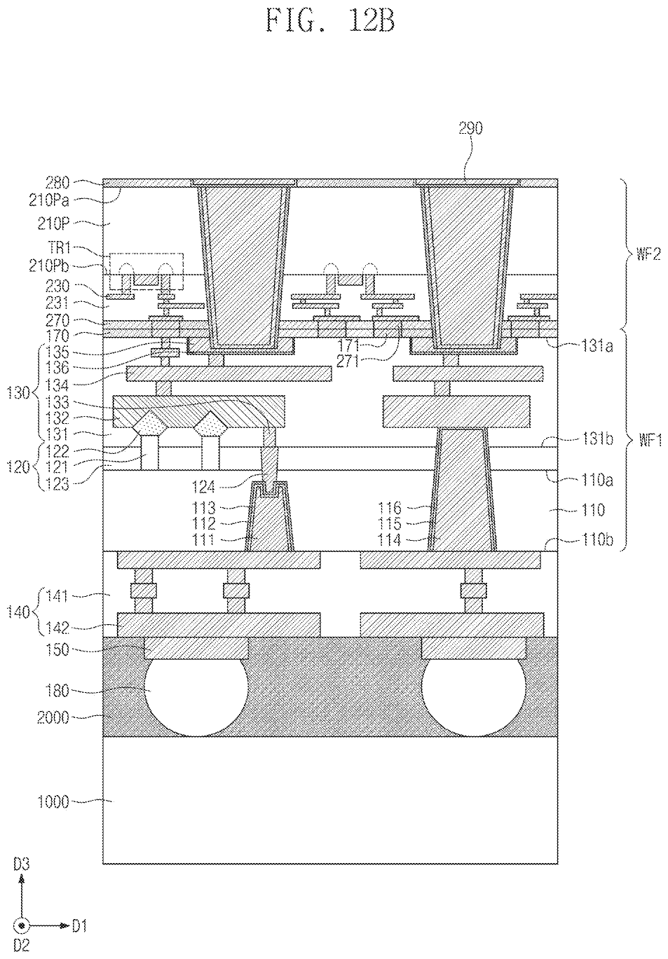

Referring to FIGS. 12A and 12B, an etching process on a top surface of the third protection layer 280 may be performed to form the third penetration via 211. For example, the formation of the third penetration via 211 may include performing an etching process on the third protection layer 280, the first semiconductor substrate 110, the device isolation layer 123, and an upper portion of the landing pad 135 to form a via hole exposing an upper portion of the landing pad 135, forming the third liner 213 on a side surface of the via hole, forming the fifth barrier metal 212 on the third liner 213 and a bottom surface of the via hole, and filling a remaining space of the via hole, which is covered with the third liner 213 and the fifth barrier metal 212, with a metallic material.

Next, the fourth barrier metal 291 and the first connection pad 290 disposed on the fourth barrier metal 291 may be formed in a space that is formed by patterning the third protection layer 280.

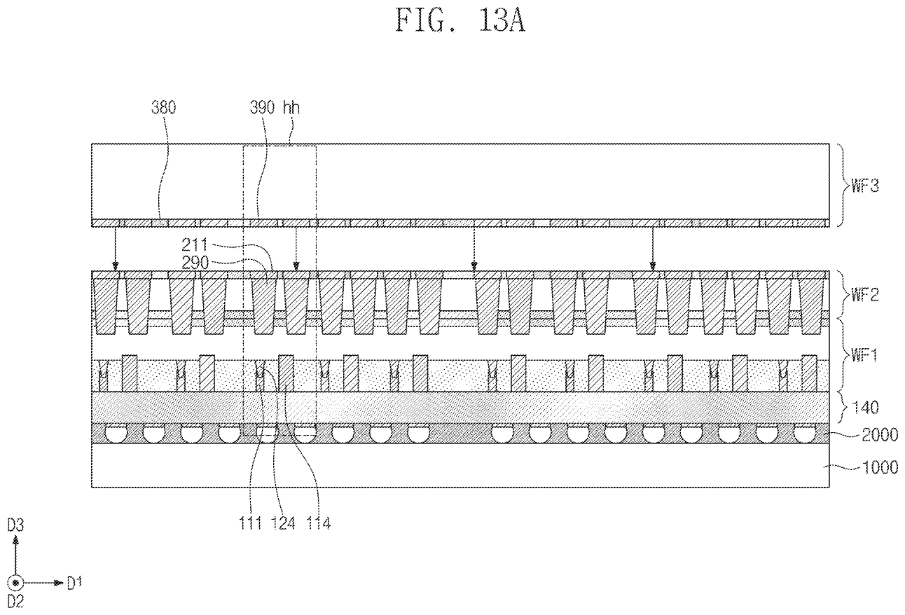

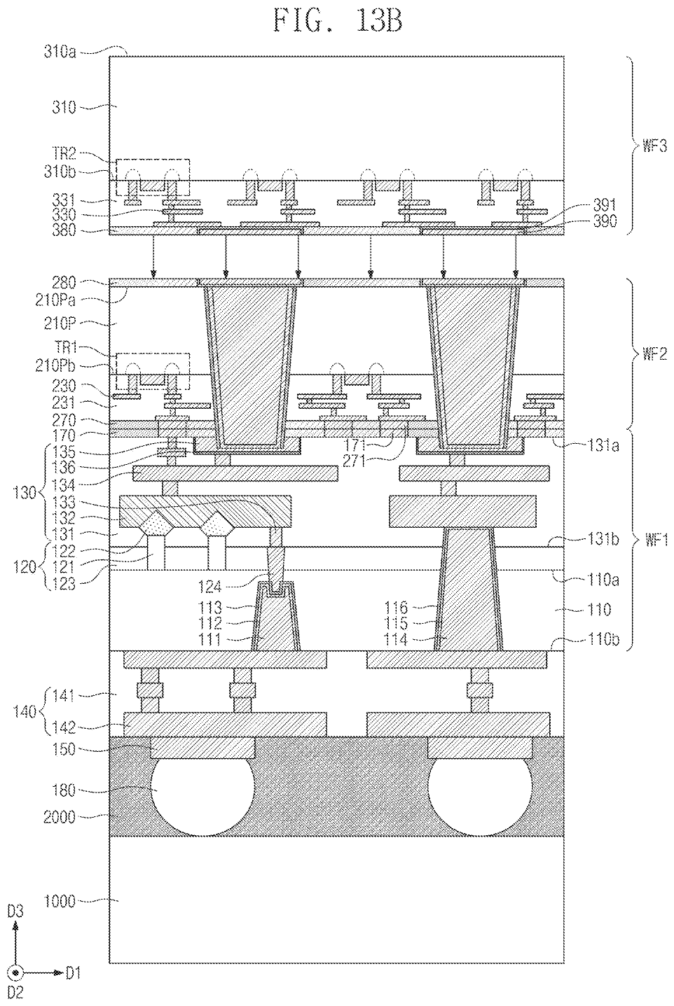

Referring to FIGS. 13A and 13B, a third wafer WF3 may be provided on the fourth protection layer 380. The third wafer WF3 may include a third preliminary semiconductor substrate 310P, the fourth interconnection layer 332, the second transistors TR2, and the fourth protection layer 380. The fourth protection layer 380 may include the second connection pad 390.

Thereafter, a wafer-to-wafer bonding process may be performed. For example, the third wafer WF3 may be in contact with the second wafer WF2. The third wafer WF3 may be directly bonded to the second wafer WF2 through a direct bonding method, without using any adhesive layer. During the bonding process, the second and third wafers WF2 and WF3 may be exposed to a thermally hot environment.

For example, the third and fourth protection layers 280 and 380 may be bonded to each other to form a hybrid bonding process. In addition, a metal-to-metal hybrid bonding process may be performed using the surface activation, at an interface between the first and second connection pads 290 and 390, which are respectively included in the third and fourth protection layers 280 and 380.

The second wafer WF2 and the third wafer WF3 may be bonded to each other by bonding the third and fourth protection layers 280 and 380 to each other and bonding the first and second connection pads 290 and 390, which are provided therein, to each other.

In an embodiment, a connection bump may be formed between the second wafer WF2 and the third wafer WF3. For example, the connection bump may be attached to a top surface of the first connection pad 290, and then, a bottom surface of the second connection pad 390 may be attached to the connection bump. That is, the connection bump may be formed to be in contact with both the first and second connection pads 290 and 390.

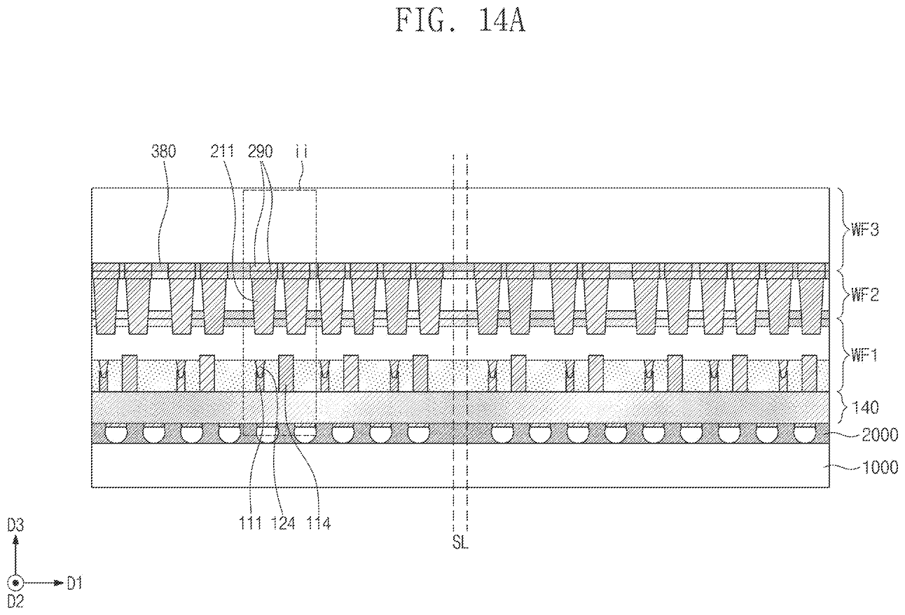

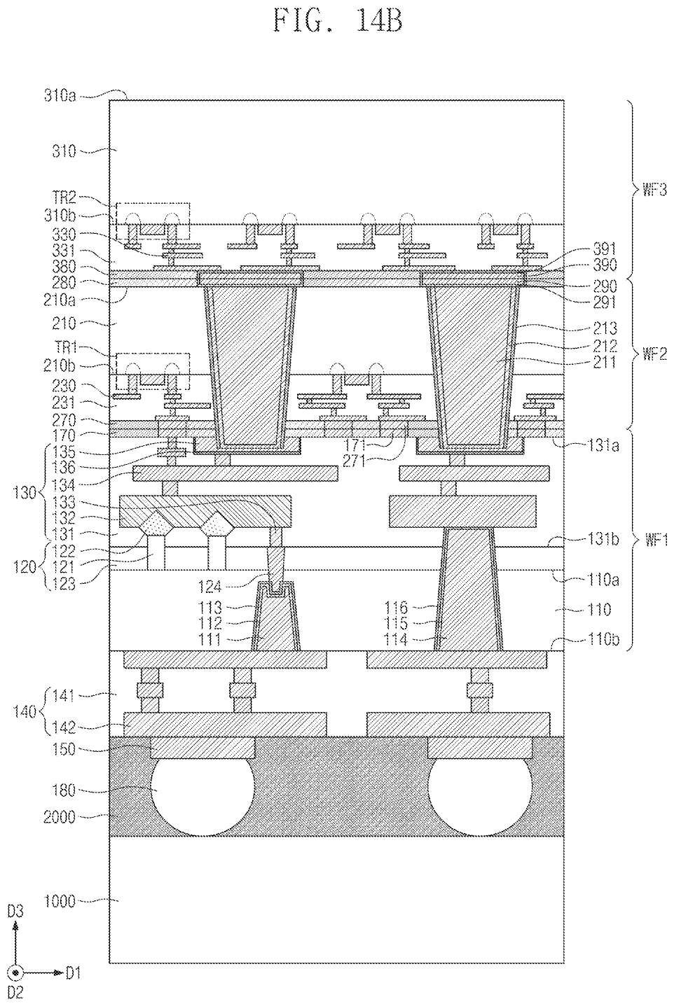

Referring to FIGS. 14A and 14B, the release layer 2000 and the carrier substrate 1000 may be removed from the second interconnection layer 140. The removal of the release layer 2000 and the carrier substrate 1000 may be performed by a physical method.

Thereafter, a sawing process may be performed along a sawing line SL. As a result of the sawing process, a plurality of chip structures 10, each of which includes the first, second, and third semiconductor chips 100, 200, and 300, may be formed.

FIGS. 13A to 14A illustrate an example in which the third wafer WF3 is bonded to the second wafer WF2 and then the chip structure 10 is formed, but the inventive concept is not limited to this example. In an embodiment, the first or second semiconductor chip 100 or 200 and the third semiconductor chip 300 may be bonded to each other in a chip-to-wafer manner. For example, the first and second wafers WF1 and WF2, which are bonded to each other, may be prepared, before a sawing process, and here, the first and second semiconductor chips 100 and 200 in the first and second wafers WF1 and WF2 may be in an unsawed state. Next, the third semiconductor chips 300 may be bonded to the second wafer WF2. Thereafter, the sawing process may be performed on the first and second wafers WF1 and WF2 to form a plurality of chip structures 10, each of which includes the first, second, and third semiconductor chips 100, 200, and 300.

Referring back to FIG. 1, a chip assembly process may be performed to mount the interposer substrate 500, the chip structure 10, and the sub-semiconductor package 20 on the package substrate 600 and to form the first mold layer 590. As a result, the semiconductor package 1 may be formed to have the structure of FIG. 1.

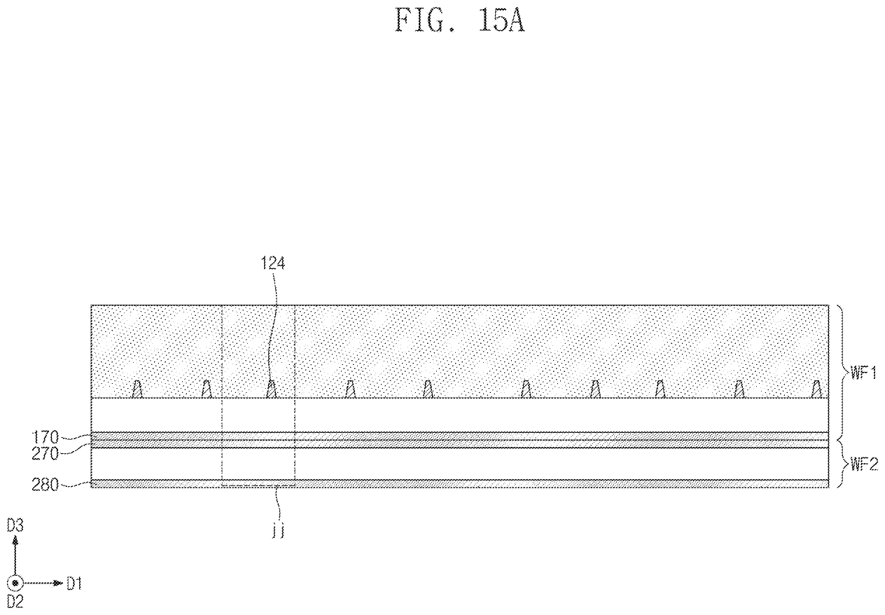

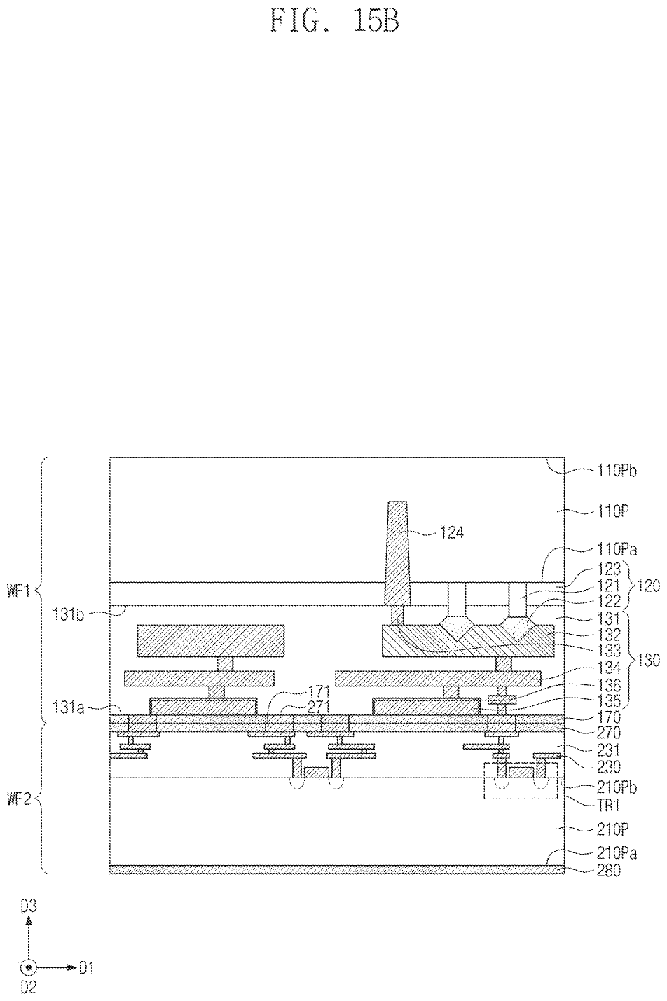

FIGS. 15A, 16A, and 17A are diagrams illustrating a method of manufacturing a semiconductor package, according to an embodiment of the inventive concept.

FIGS. 15B, 16B, and 17B are enlarged views illustrating portions ‘jj’, ‘kk’, and ‘ll’ of FIGS. 15A, 16A, and 17A, respectively.

Referring to FIGS. 15A and 15B, the first and second wafers WF1 and WF2 may be provided. The first and second wafers WF1 and WF2 may include substantially the same element as that in the embodiment of FIGS. 5A and 5B.

Thereafter, a wafer-to-wafer bonding process may be performed. For example, the second wafer WF2 may be placed on and in contact with the first wafer WF1. The bonding process may be performed in substantially the same manner as that in an embodiment of FIGS. 6A and 6B.

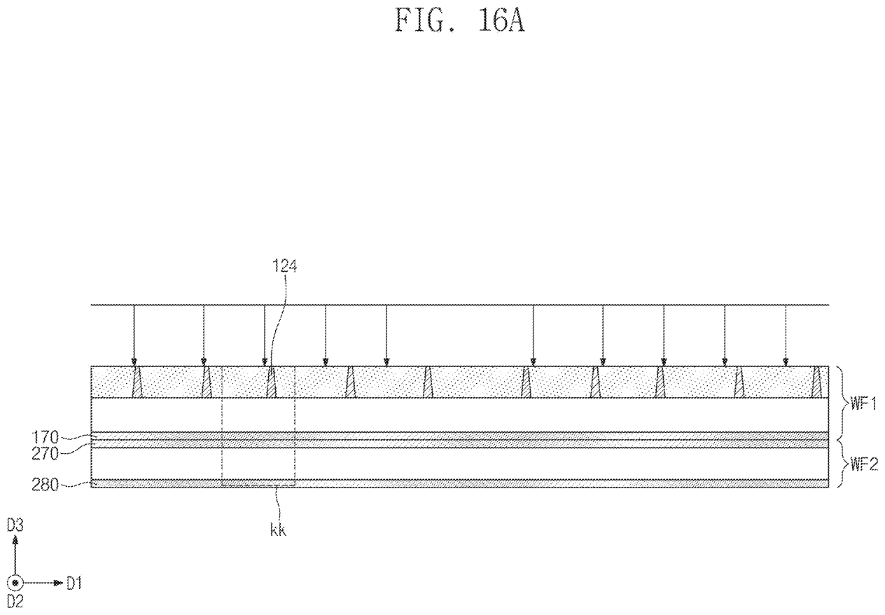

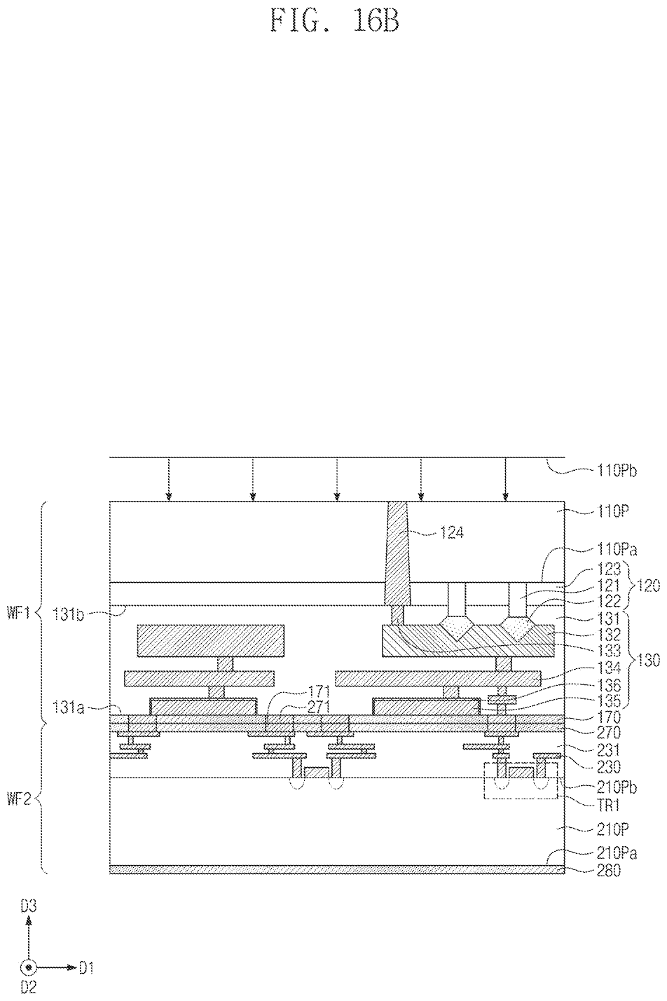

Referring to FIGS. 16A and 16B, a grinding process, a chemical-mechanical polishing (CMP) process, or a dry etching process may be performed on the eighth surface 110Pb of the first preliminary semiconductor substrate 110P to remove a portion of the first preliminary semiconductor substrate 110P. The etching process may be performed to expose a bottom surface of the buried power rail 124. A thickness of the first preliminary semiconductor substrate 110P in the third direction D3 may be reduced by the etching process. The first semiconductor substrate 110 may be formed as a result of reducing the thickness of the first preliminary semiconductor substrate 110P.

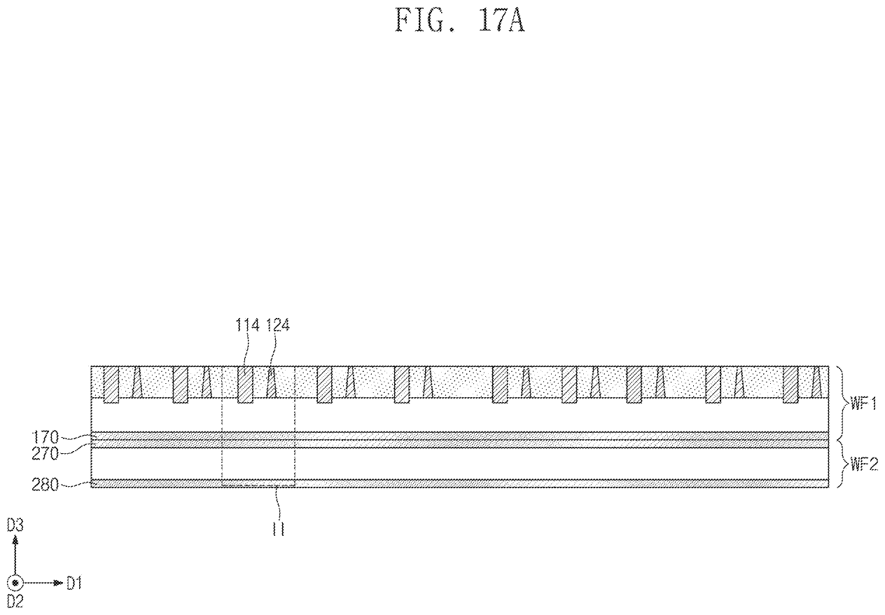

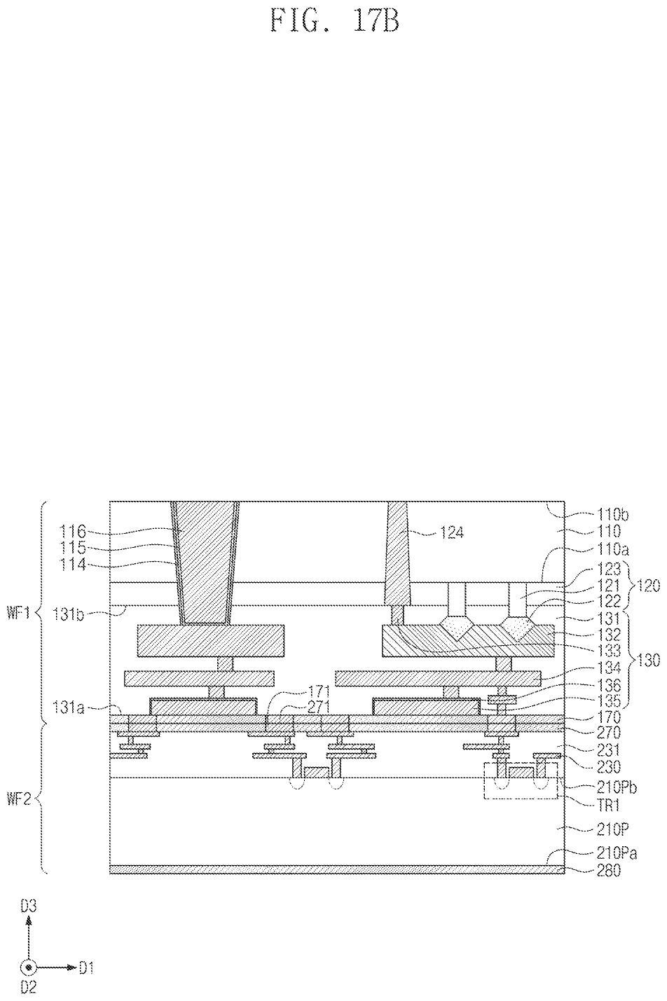

Referring to FIGS. 17A and 17B, the second penetration via 114 may be formed in the first wafer WF1. The formation of the second penetration via 114 may include performing an etching process on the first semiconductor substrate 110 and the device isolation layer 123 to form a via hole exposing the first interconnection line 134, forming the second liner 116 on a side surface of the via hole, forming the third barrier metal 115 on the second liner 116 and a bottom surface of the via hole, and filling the via hole, which is covered with the second liner 116 and the third barrier metal 115, with a metallic material.

Thereafter, the processes of FIGS. 9A to 14A may be repeated, and a chip assembly process may be performed to mount the interposer substrate 500, the chip structure 10, and the sub-semiconductor package 20 on the package substrate 600 and to form the first mold layer 590. The semiconductor package according to an embodiment of the inventive concept may be formed through the method described above.

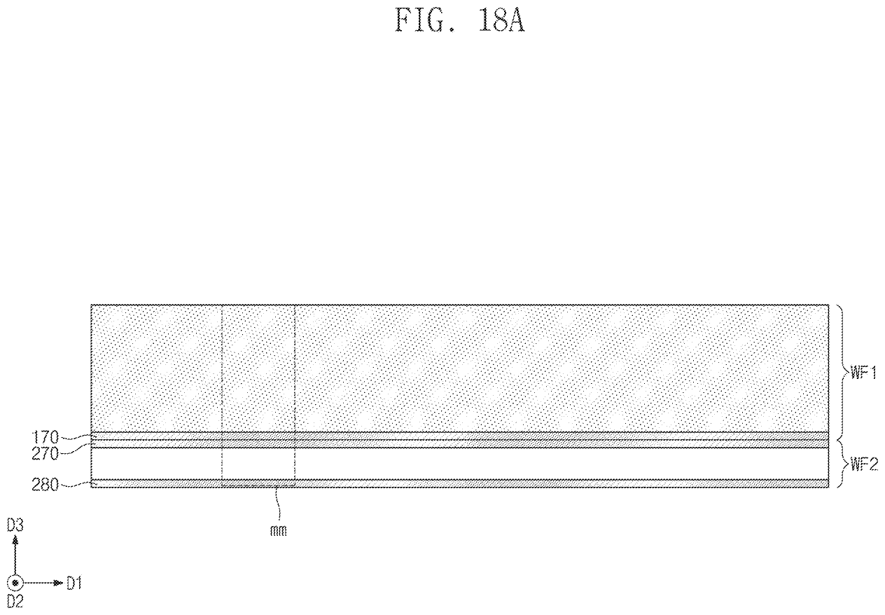

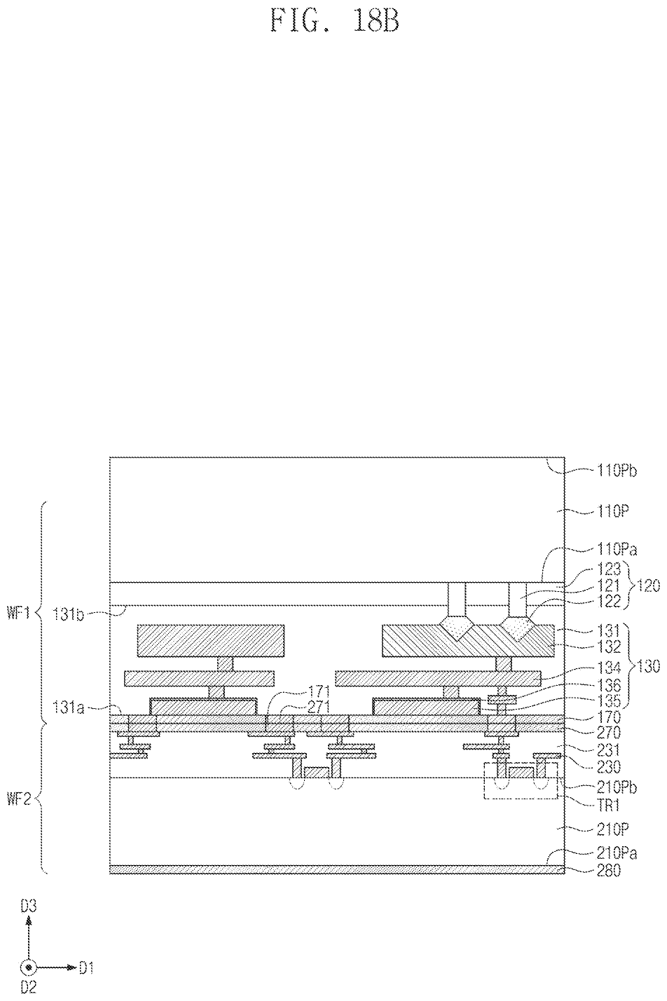

FIGS. 18A, 19A, and 20A are diagrams illustrating a method of manufacturing a semiconductor package, according to an embodiment of the inventive concept.

FIGS. 18B, 19B, and 20B are enlarged views illustrating portions ‘mm’, ‘nn’, and ‘oo’ of FIGS. 18A, 19A, and 20A, respectively.

Referring to FIGS. 18A and 18B, the first and second wafers WF1 and WF2 may be provided. In an embodiment, the first and second wafers WF1 and WF2 do not include the power rail, which is buried in the first wafer WF1, and except for this difference, the first and second wafers WF1 and WF2 may be configured to have substantially the same structure as those of FIGS. 5A and 5B.

Thereafter, a wafer-to-wafer bonding process may be performed. For example, the second wafer WF2 may be placed on and in contact with the first wafer WF1. The bonding process may be performed using substantially the same method as described with reference to FIG. 6A to 6B.

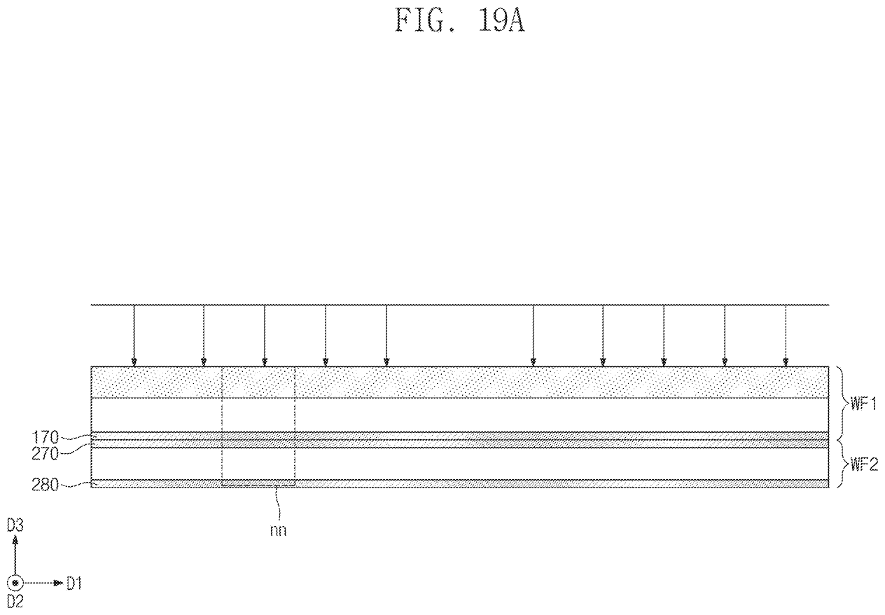

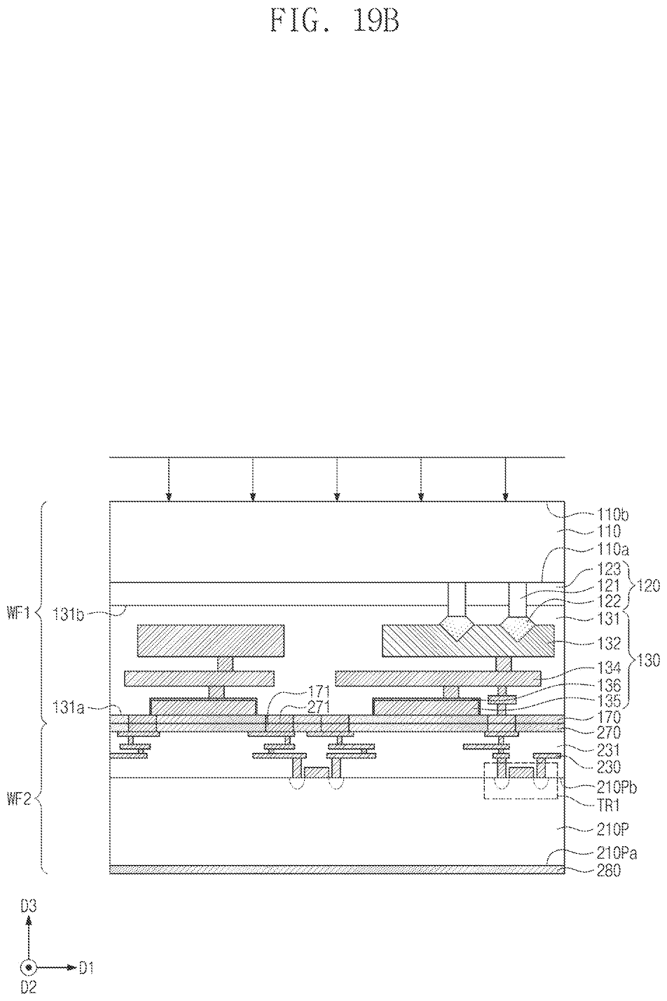

Referring to FIGS. 19A and 19B, a portion of the first preliminary semiconductor substrate 110P may be removed by performing a chemical-mechanical polishing (CMP) process, a dry etching process, or a grinding process on the eighth surface 110Pb of the first preliminary semiconductor substrate 110P. A thickness of the first preliminary semiconductor substrate 110P in the third direction D3 may be reduced by the etching process. The thickness of the first preliminary semiconductor substrate 110P after the etching process is performed may be substantially equal to the fourth height H4 of the fourth penetration via 181 that will be formed by a process to be described below. The first semiconductor substrate 110 may be formed as a result of reducing the thickness of the first preliminary semiconductor substrate 110P.

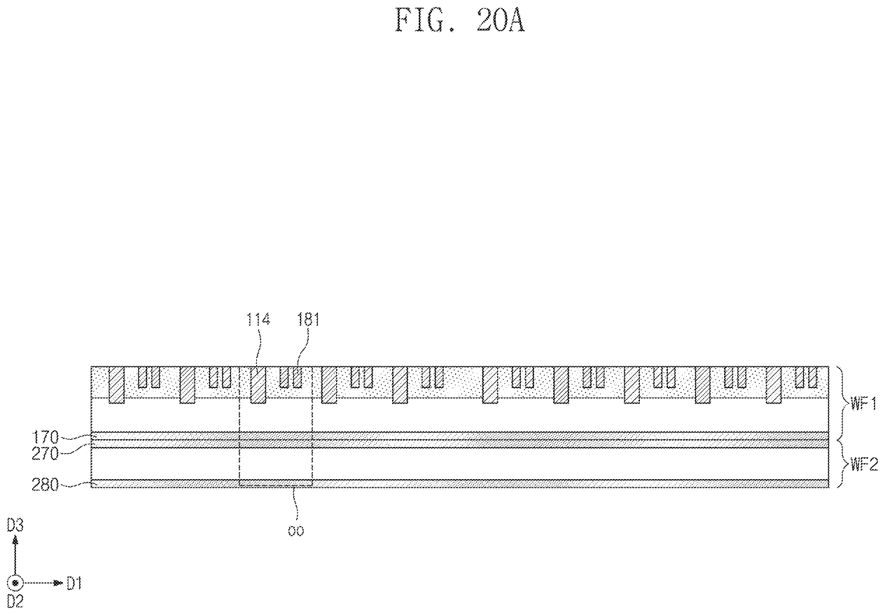

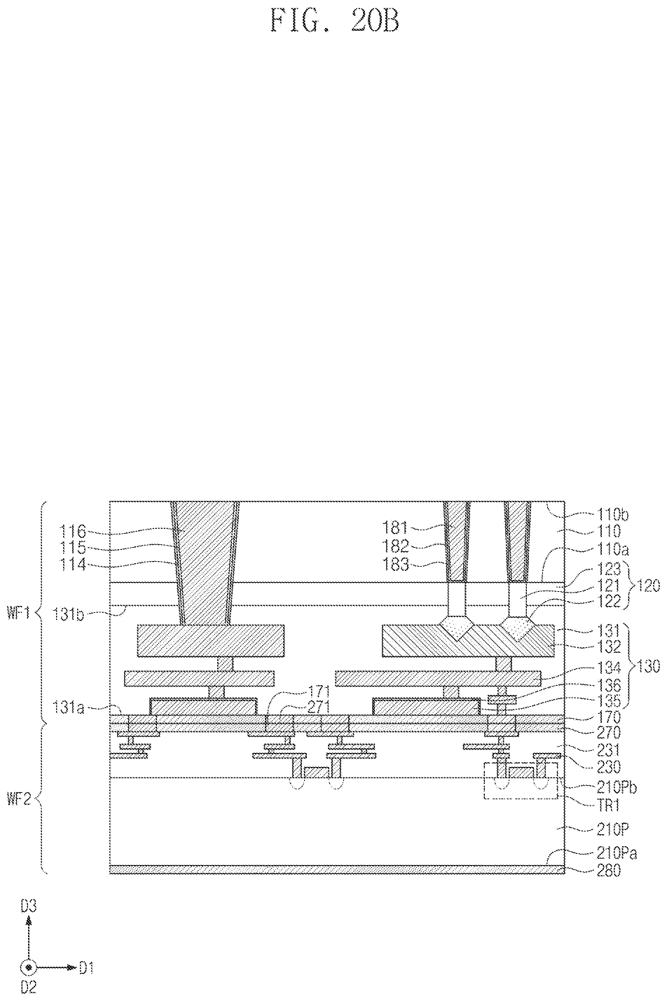

Referring to FIGS. 20A and 20B, the fourth penetration via 181 may be formed in the first wafer WF1. The forming of the fourth penetration via 181 may include performing an etching process on the first semiconductor substrate 110 to form a via hole exposing a bottom surface of the fin 121, forming the fourth liner 183 on a side surface of the via hole, forming the sixth barrier metal 182 on the fourth liner 183, and filling a remaining portion of the via hole, which is covered with the fourth liner 183 and the sixth barrier metal 182, with a metallic material. Next, the process described with reference to FIGS. 7A and 7B may be repeated to form the second penetration via 114 that is formed spaced apart from the fourth penetration via 181 in the first direction D1.

Thereafter, the processes of FIGS. 8A to 14A may be repeated, and a chip assembly process may be performed to mount the interposer substrate 500, the chip structure 10, and the sub-semiconductor package 20 on the package substrate 600 and to form the first mold layer 590. The semiconductor package according to an embodiment of the inventive concept may be formed through the method described above.

Referring to a process of fabricating a semiconductor package according to a comparative example, there may be a wafer warpage issue during a pad aligning process. This may lead to the deterioration in the structural stability of the semiconductor package.

By contrast, referring to a process of fabricating a semiconductor package according to an embodiment of the inventive concept, the semiconductor chips may be connected to each other through the hybrid bonding structure between the protection layers 170, 270, 280, and 380 and using the third penetration via 211, and in this case, it may be possible to improve the structural stability of the semiconductor package 1 and reduce the wafer warpage issue.

According to an embodiment of the inventive concept, a semiconductor package may include a first semiconductor chip, a third semiconductor chip disposed on the first semiconductor chip, and a second semiconductor chip disposed between the first semiconductor chip and the third semiconductor chip. The first semiconductor chip may be a logic chip. The second semiconductor chip and the third semiconductor chip may be a logic chip or a memory chip, and the first semiconductor chip and the second semiconductor chip may be connected to each other through a penetration via in the second semiconductor chip. Since the semiconductor chips are electrically connected to each other through the penetration via, the operation efficiency of the semiconductor package may be improved. The semiconductor chips may be bonded to each other through a hybrid bonding structure between protection layers, and this may make it possible to improve the structural stability of the semiconductor package. In addition, since signal lines and power distribution lines are respectively provided in upper and lower portions of the first semiconductor chip, it may be possible to reduce a size of the semiconductor package.

While the inventive concept has been particularly shown and described with reference to embodiments thereof, it will be understood by those of ordinary skill in the art that various changes in form and detail may be made therein without departing from the spirit and scope of the inventive concept as defined by the following claims.

What is claimed is:

1. A semiconductor package, comprising:
a first semiconductor chip; and
a second semiconductor chip disposed on the first semiconductor chip,
wherein the first semiconductor chip comprises:
a first semiconductor substrate including a first surface and a second surface facing each other;
a first circuit layer disposed on the first surface;
a first interconnection layer disposed on the first circuit layer, the first interconnection layer comprising a landing pad;
a second interconnection layer disposed on the second surface; and
a first penetration via protruding from the second interconnection layer and penetrating the first semiconductor substrate,
wherein the second semiconductor chip comprises:
a second semiconductor substrate including a third surface and a fourth surface facing each other, the fourth surface being closer to the first semiconductor chip than the third surface is to the first semiconductor chip,
a third interconnection layer disposed on the fourth surface;
a second circuit layer disposed between the third interconnection layer and the fourth surface; and
a second penetration via penetrating the second semiconductor substrate and connected to the landing pad.

2. The semiconductor package of claim 1, wherein the first semiconductor chip further comprises:
a vertical contact protruding from the first interconnection layer toward the first semiconductor substrate; and
a buried power rail disposed on the vertical contact and penetrating the first surface of the first semiconductor substrate,
wherein the first penetration via is connected to the buried power rail.

3. The semiconductor package of claim 1, wherein the first interconnection layer comprises a plurality of signal lines, and
the second interconnection layer comprises a plurality of power distribution lines.

4. The semiconductor package of claim 2, further comprising:
a third penetration via protruding from the second interconnection layer and penetrating the first semiconductor substrate,
wherein the third penetration via extends into the first interconnection layer.

5. The semiconductor package of claim 4, wherein the first penetration via is a power via, and
the third penetration via is a signal via.

6. The semiconductor package of claim 1, further comprising:
a third semiconductor chip disposed on the second semiconductor chip,
wherein the third semiconductor chip comprises:
a third semiconductor substrate including a fifth surface and a sixth surface,
wherein the sixth surface is disposed closer to the second semiconductor chip than the fifth surface is to the second semiconductor chip and faces the fifth surface;
a fourth interconnection layer disposed on the sixth surface; and
a third circuit layer disposed between the fourth interconnection layer and the sixth surface.

7. The semiconductor package of claim 1,
wherein the first semiconductor chip further comprises:
a first protection layer disposed on the first interconnection layer,
wherein the second semiconductor chip further comprises:
a second protection layer disposed below the third interconnection layer,
wherein the first protection layer and the second protection layer are in contact with each other.

8. The semiconductor package of claim 7,
wherein the second semiconductor chip further comprises:
a third protection layer disposed on the third surface,
wherein the third semiconductor chip further comprises:
a fourth protection layer disposed below the fourth interconnection layer,
wherein the third protection layer and the fourth protection layer are in contact with each other.

9. The semiconductor package of claim 6, further comprising:
a plurality of connection bumps disposed between the second semiconductor chip and the third semiconductor chip.

10. The semiconductor package of claim 7, wherein the second penetration via penetrates the first protection layer and the second protection layer.

11. The semiconductor package of claim 4, wherein the first penetration via has a first width in a first direction substantially parallel to a top surface of the first semiconductor substrate,
the second penetration via has a second width in the first direction,
the third penetration via has a third width in the first direction,
the first width ranges from about 10 nm to about 100 nm,
the second width is less than or equal to about 100 μm, and
the third width is greater than or equal to about 100 nm and is less than about 1 μm.

12. A semiconductor package, comprising:
a first semiconductor chip; and
a second semiconductor chip disposed on the first semiconductor chip,
wherein the first semiconductor chip comprises:
a first semiconductor substrate including a first surface and a second surface facing each other;
a first circuit layer disposed on the first surface;
a first interconnection layer disposed on the first circuit layer;
a second interconnection layer disposed on the second surface; and
a first penetration via protruding from the second interconnection layer and penetrating the first semiconductor substrate,
wherein the second semiconductor chip comprises:
a second semiconductor substrate including a third surface and a fourth surface,
wherein the fourth surface is closer to the first semiconductor chip than the third surface is to the first semiconductor chip and faces the third surface,
a third interconnection layer disposed on the fourth surface;
a second circuit layer disposed between the third interconnection layer and the fourth surface; and
a second penetration via penetrating the second semiconductor substrate,
wherein the first penetration via has a first width in a first direction substantially parallel to a top surface of the first semiconductor substrate and a first height in a second direction substantially perpendicular to the top surface of the first semiconductor substrate,
the second penetration via has a second width in the first direction and a second height in the second direction,
the second width is larger than the first width,
the second height is larger than the first height, and
the first penetration via has a shape that is tapered in an opposite manner to the second penetration via.

13. The semiconductor package of claim 12, further comprising:
a third semiconductor chip disposed on the second semiconductor chip,
wherein the third semiconductor chip comprises:
a third semiconductor substrate including a fifth surface and a sixth surface,
wherein the sixth surface is closer to the second semiconductor chip than the fifth surface is to the second semiconductor chip and faces the fifth surface,
a fourth interconnection layer disposed on the sixth surface; and
a third circuit layer disposed on the fourth interconnection layer.

14. The semiconductor package of claim 12, wherein the second width is less than or equal to about 100 μm.

15. A semiconductor package, comprising:
a package substrate;
an interposer substrate disposed on the package substrate;
a chip stack and a chip structure, which are spaced apart from each other in a first direction substantially parallel to a top surface of the interposer substrate; and
a mold layer covering a side surface of the chip stack, a side surface of the chip structure, and the top surface of the interposer substrate,
wherein the chip structure comprises:
a first semiconductor chip;
a third semiconductor chip disposed on the first semiconductor chip; and
a second semiconductor chip disposed between the first semiconductor chip and the third semiconductor chip,
wherein the first semiconductor chip comprises:
a first semiconductor substrate including a first surface and a second surface facing each other;
a first circuit layer disposed on the first surface, the first circuit layer comprising a plurality of fins, an epitaxial pattern, and a landing pad;
a first interconnection layer disposed on the first circuit layer;
a second interconnection layer disposed on the second surface; and
a first penetration via and a second penetration via protruding from the second interconnection layer toward the first surface,
wherein the first interconnection layer comprises a signal line,
the second interconnection layer comprises a power distribution line,
an end portion of the first penetration via is disposed at a level lower than or about equal to the first surface, and
an end portion of the second penetration via is disposed at a level higher than the first surface,
wherein the second semiconductor chip comprises:
a second semiconductor substrate including a third surface and a fourth surface,
wherein the fourth surface is closer to the first semiconductor chip than the third surface is to the first semiconductor chip and faces the third surface;
a third interconnection layer disposed on the fourth surface;
a second circuit layer disposed between the third interconnection layer and the fourth surface; and
a third penetration via penetrating the second semiconductor substrate and connected to the first interconnection layer.

16. The semiconductor package of claim 15, wherein the second penetration via extends into the first interconnection layer.

17. The semiconductor package of claim 15, wherein the first penetration via has a first width in the first direction,
the second penetration via has a second width in the first direction, and
the second width is larger than the first width.

18. The semiconductor package of claim 17, wherein the first width is less than or equal to about 50 nm,
the second width is larger than or equal to about 100 nm and is less than about 1 μm,
the third penetration via has a third width in the first direction, and
the third width is less than or equal to about 100 μm.

19. The semiconductor package of claim 18, wherein the first penetration via has a first height in a second direction substantially perpendicular to the top surface of the interposer substrate, and
the first height is less than or equal to about three times the first width.

20. The semiconductor package of claim 18, wherein the third penetration via has a second height in a second direction substantially perpendicular to the top surface of the interposer substrate, and
the second height is less than or equal to about 20 times the third width.
